(19) United States
(12) Patent Application Publication
(10) Pub. No.: US 2024/0313049 A1
(43) Pub. Date: Sep. 19, 2024

(54) SEMICONDUCTOR DEVICES HAVING ENHANCED KEY PATTERNS THEREIN AND METHODS OF FABRICATING SAME

(71) Applicant: Samsung Electronics Co., Ltd., Suwon-si (KR)

(72) Inventors: Byounghoon KIM, Suwon-si (KR); Hyunwoong KIM, Suwon-si (KR); Sungsik PARK, Suwon-si (KR); Jonghwa BAEK, Suwon-si (KR); KyungMin SUH, Suwon-si (KR); Hyunju SONG, Suwon-si (KR); Myoungki JUNG, Suwon-si (KR)

(21) Appl. No.: 18/394,926

(22) Filed: Dec. 22, 2023

(30) Foreign Application Priority Data
Mar. 15, 2023 (KR) 10-2023-0034197

(51) Int. Cl. H01L 29/06; H01L 27/092; H01L 29/417; H01L 29/423; H01L 29/66; H01L 29/775; H01L 29/786

(52) U.S. Cl. CPC H01L 29/0673; H01L 27/092; H01L 29/41733; H01L 29/42392; H01L 29/6656; H01L 29/775; H01L 29/78696

(57) ABSTRACT

A semiconductor device includes a substrate having a key region therein, a device isolation layer on the key region, first key patterns on the device isolation layer, and a dummy key pattern extending between the first key patterns, which are adjacent to each other. The first key patterns include a plurality of first sub-key patterns, and the dummy key pattern includes a separation structure, which extends into the device isolation layer and through at least one of the plurality of first sub-key patterns. A first pitch between the plurality of first sub-key patterns may be substantially the same as a second pitch between the separation structure and one of the plurality of first sub-key patterns adjacent thereto.

### REFERENCE TO PRIORITY APPLICATION

This U.S. non-provisional patent application claims priority under 35 U.S.C. § 119 to Korean Patent Application No. 10-2023-0034197, filed Mar. 15, 2023, the entire contents of which are hereby incorporated herein by reference.

### BACKGROUND OF THE INVENTION

The present disclosure relates to semiconductor devices and, more particularly, to semiconductor devices and integrated circuits that utilize key patterns and methods of manufacturing the same.

Due to their small-sized, multifunctional, and/or low-cost characteristics, semiconductor devices are appreciated as important elements in the electronics industry. Semiconductor devices can be classified into a memory device for storing data, a logic device for processing data, and a hybrid device including both of memory and logic elements. To meet the increased demand for electronic devices with fast speed and/or low power consumption, it is necessary to realize semiconductor devices with high reliability, high performance, and/or multiple functions. To satisfy these technical requirements, the complexity and/or integration density of semiconductor devices continues to be increased.

As the integration of semiconductor devices increases, a density of patterns formed on a unit area of a substrate also typically increases. In addition, as semiconductor devices become multi-functional and higher performance, the number of layers formed on a substrate increases. Accordingly, it is necessary to accurately form patterns at predetermined positions during a manufacturing process of a semiconductor device. Therefore, an alignment key or an overlay key for aligning layers stacked on a substrate may be used to improve semiconductor device and manufacturing yield and reliability.

### SUMMARY

An object of the present disclosure is to provide a semiconductor device with improved reliability and yield.

An object of the present disclosure is to provide a method of manufacturing a semiconductor device with improved overlay measurement performance.

A semiconductor device according to some embodiments of the present disclosure may include a substrate containing: a key region, a device isolation layer on the key region, first key patterns on the device isolation layer, and dummy key patterns extending between adjacent ones of the first key patterns. In some embodiments, the first key patterns may include a plurality of first sub-key patterns, whereas the dummy key pattern may include a separation structure extending into the device isolation layer and through at least one of the plurality of first sub-key patterns. In some of these embodiments, a first pitch between the plurality of first sub-key patterns may be substantially the same as a second pitch between the separation structure and one of the plurality of first sub-key patterns adjacent thereto.

A semiconductor device according to additional embodiments of the present disclosure may include a substrate containing: a key region, a device isolation layer on the key region, first key patterns on the device isolation layer, and dummy key patterns extending between adjacent first key patterns. The first key patterns may be spaced apart from each other by the dummy key patterns, and each of the first key patterns may include a first sub-key pattern, a first spacer on a sidewall of the first sub-key pattern, and a capping pattern on the first sub-key pattern. Moreover, the dummy key pattern may include a separation structure and a second spacer on a sidewall of the separation structure, and an upper surface of the capping pattern may be coplanar with an upper surface of the separation structure.

A semiconductor device according to some embodiments of the present disclosure may include a substrate containing: a key region, a device isolation layer on the key region, a first single diffusion brake and a second single diffusion brake on the device isolation layer, a plurality of first sub-key patterns arranged between the first and second single diffusion brakes, and a second sub key pattern extending between the first sub-key pattern adjacent to the second single diffusion break among the plurality of first sub-key patterns and the second single diffusion break. In some of these embodiments, a first pitch between the adjacent first sub-key pattern and the second sub-key pattern may be different from a second pitch between the second sub-key pattern and the second single diffusion break.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a semiconductor device according to embodiments of the present disclosure.

FIG. 2 is a plan view illustrating a logic cell region of FIG. 1 for explaining a semiconductor device according to an embodiment of the present disclosure.

FIGS. 3A to 3D are cross-sectional views taken along lines A-A′, B-B′, C-C′, and D-D′ of FIG. 2, respectively.

FIG. 4 is a plan view illustrating a key region of FIG. 1 for explaining a semiconductor device according to an embodiment of the present disclosure.

FIGS. 5A to 5C are cross-sectional views taken along lines A-A′, B-B′, and C-C′ of FIG. 4, respectively.

FIG. 6 illustrates a cross-section taken along the line A-A′ of FIG. 4 for explaining a semiconductor device according to a comparative example of the present disclosure.

FIGS. 7, 9, 11, and 13 are plan views for explaining a method of manufacturing a semiconductor device according to embodiments the present disclosure.

FIGS. 8, 10A, 12A, and 14A are cross-sectional views taken along lines A-A′ of FIGS. 7, 9, 11, and 13, respectively.

FIGS. 10B, 12B, and 14B are cross-sectional views taken along line B-B′ of FIGS. 9, 11, and 13, respectively.

FIG. 14C is a cross-sectional view taken along line C-C′ of FIG. 13.

FIG. 15 is a plan view illustrating a key region of FIG. 1 for explaining a semiconductor device according to another embodiment of the present disclosure.

FIGS. 16A to 16C are cross-sectional views taken along lines A-A′, B-B′, and C-C′ of FIG. 15, respectively.

### DETAILED DESCRIPTION

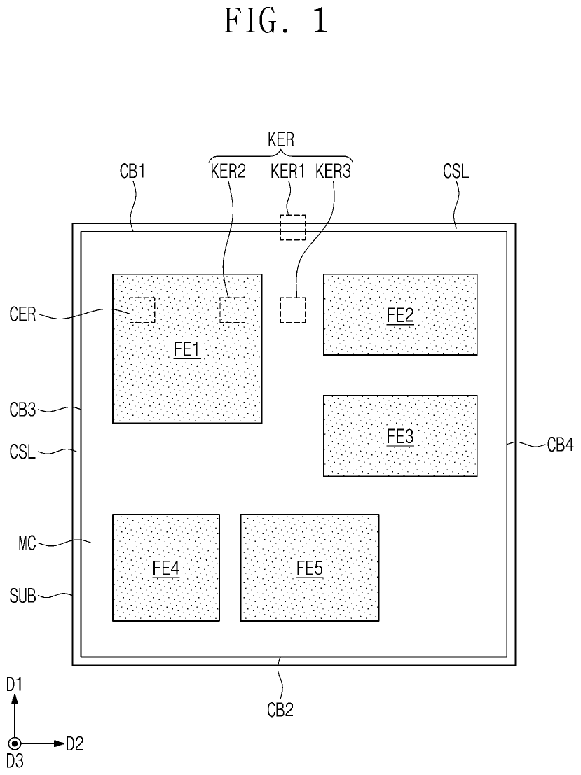

FIG. 1 is a plan view illustrating a semiconductor device according to embodiments of the present disclosure. Referring to FIG. 1, a semiconductor device may include a main chip MC and cut scribe lanes CSL surrounding the main chip MC. The main chip MC may include first to fifth functional units FE1 to FE5 on a substrate 100. The substrate 100 may be obtained from a diced semiconductor wafer. The substrate 100 may support the first to fifth functional units FE1 to FE5. In some embodiments, the main chip MC may include first to fourth boundaries CB1 to CB4. The first to fourth boundaries CB1 to CB4 may be defined between the cut scribe lane CSL and the main chip MC. The cut scribe lane CSL may surround the first to fourth boundaries CB1 to CB4 of the main chip MC. As an example, the cut scribe lane CSL may include a first key region KER1 adjacent to the first boundary CB1 of the main chip MC. That is, the first key region KER1 may remain on the cut scribe lane CSL even after a wafer dicing process.

Each of the first to fifth functional units FE1 to FE5 may be a functional block constituting an integrated circuit. Each of the first to fifth functional units FE1 to FE5 may include one of a memory block, an analog logic block, an input/output (I/O) logic block, a central processing unit (CPU) block, and a radio frequency block. For example, in some embodiments, the first functional unit FE1 may include a logic cell region CER and a second key region KER2. Thus, the key region KER may be provided not only in the scribe lane, as KER1, but also in a functional block. Moreover, a third key region KER3 may be provided in a region between the first and second functional units FE1 and FE2, as shown. The key regions KER according to embodiments may include first to third key regions KER1, KER2, and KER3 disposed at different locations on the semiconductor device. In a semiconductor device, that is, a semiconductor chip, at least one of the illustrated first to third key regions KER1, KER2, and KER3 may be omitted. As will be understood by those skilled in the art, the key region KER may include key patterns to be described later. The key pattern may include an overlay key, an alignment key, or a combination thereof.

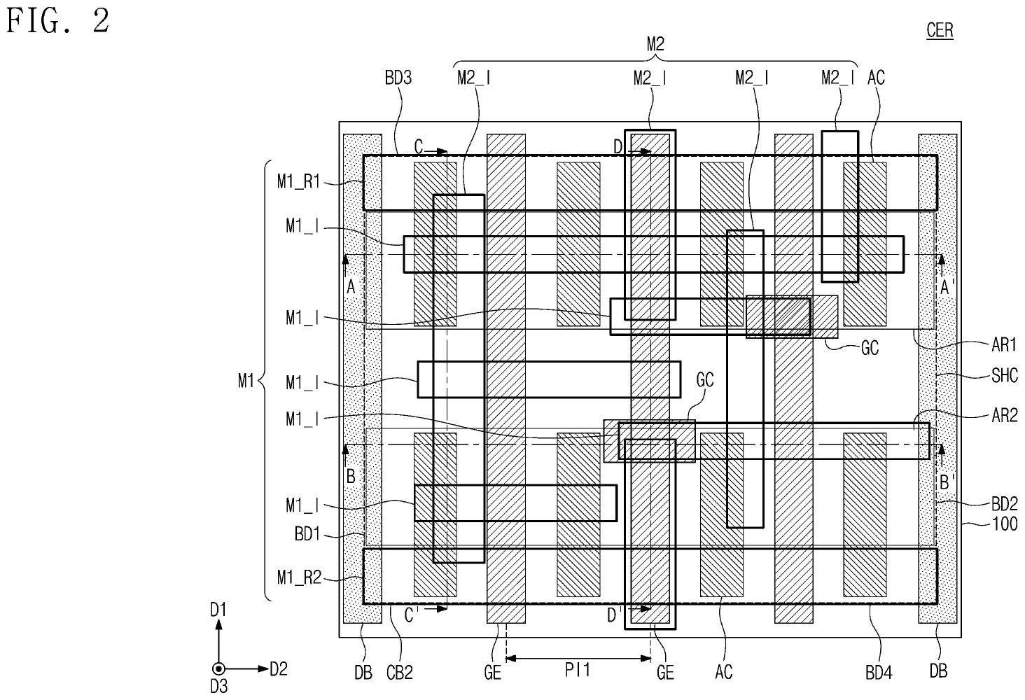

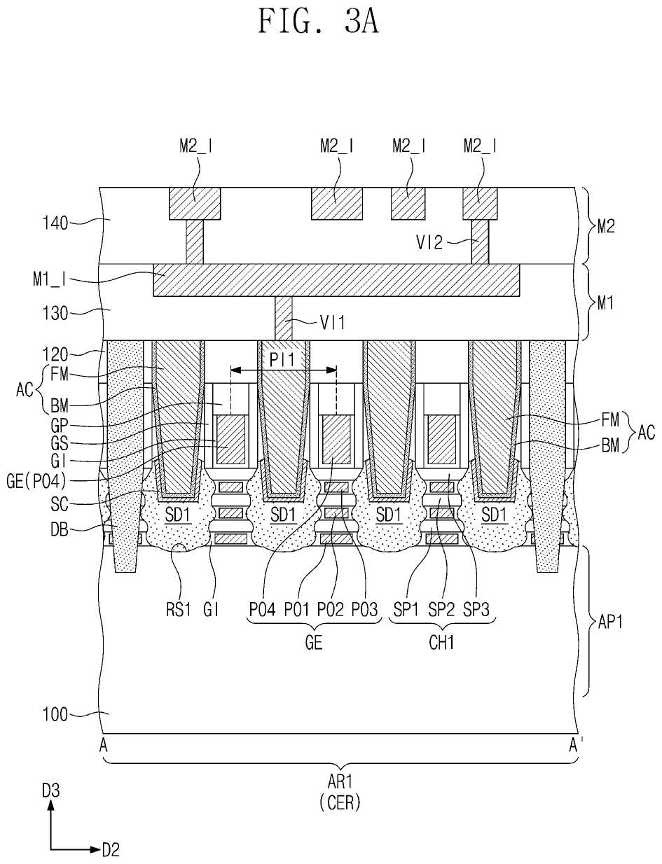

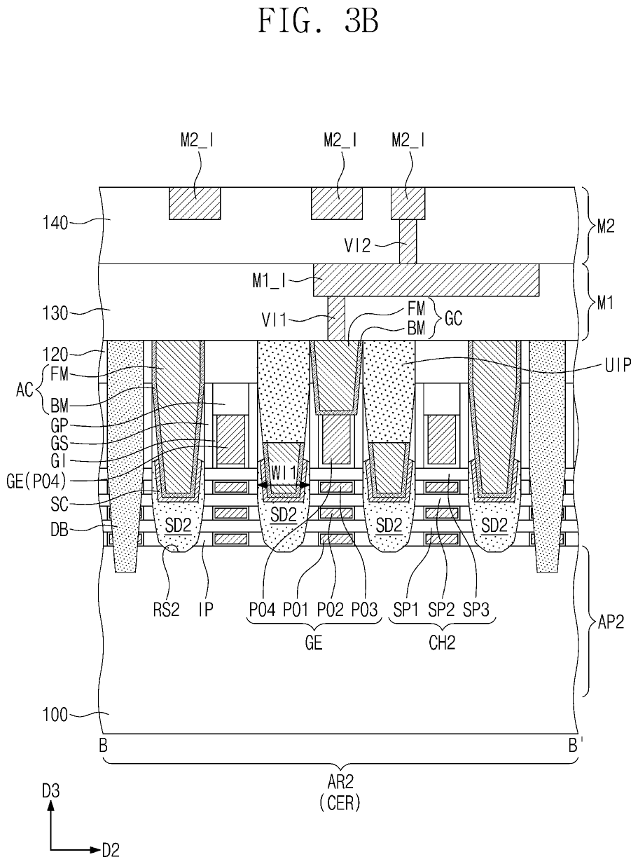

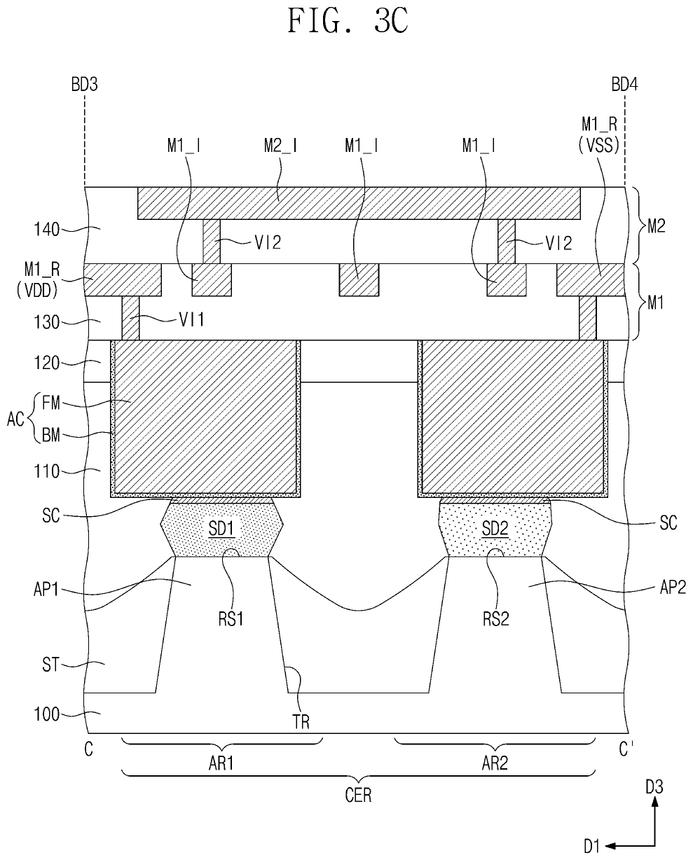

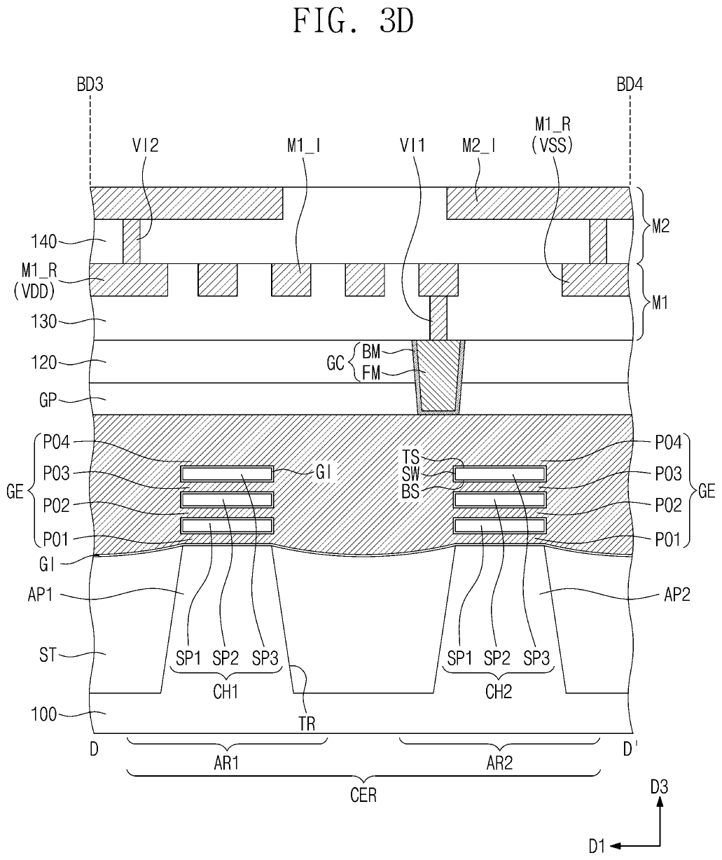

FIG. 2 is a plan view illustrating a logic cell region of FIG. 1 for explaining a semiconductor device according to an embodiment of the present disclosure. FIGS. 3A to 3D are cross-sectional views taken along lines A-A′, B-B′, C-C′, and D-D′ of FIG. 2, respectively. Referring to FIGS. 2 and 3A to 3D, the first functional unit FE1 of the semiconductor chip shown in FIG. 1 may include a logic cell region CER. The logic cell region CER may include logic cells representing logic elements (e.g., AND, OR, XOR, XNOR, inverter, etc.) that perform a specific function, such as a boolean function. The logic cell SHC of the logic cell region CER may include transistors constituting logic elements and wirings connecting the transistors to each other. A substrate 100 may be a semiconductor substrate including silicon, germanium, silicon-germanium, or the like, or a compound semiconductor substrate. For example, the substrate 100 may be a silicon substrate.

The substrate 100 may include a first active region AR1 and a second active region AR2. Each of the first and second active regions AR1 and AR2 may extend in a second direction D2. As an example, the first active region AR1 may be a PMOSFET region, and the second active region AR2 may be an NMOSFET region. The first active pattern AP1 and the second active pattern AP2 may be defined by a trench TR formed on an upper surface of the substrate 100. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 are portions of the substrate 100 and may be vertically protruding portions.

A device isolation layer ST may be provided on the substrate 100. The device isolation layer ST may fill the trench TR. The device isolation layer ST may include a silicon oxide layer. The device isolation layer ST may not cover first and second channel patterns CH1 and CH2 to be described later. A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3 sequentially stacked. The first to third semiconductor patterns SP1, SP2, and SP3 may be spaced apart from each other in a vertical direction (i.e., in a third direction D3).

Each of the first to third semiconductor patterns SP1, SP2, and SP3 may be a nanosheet. That is, each of the first and second channel patterns CH1 and CH2 may be a stack including stacked nanosheets. Each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon.

A plurality of first source/drain patterns SD1 may be provided on the first active pattern AP1. A plurality of first recesses RS1 may be formed on the first active pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between the pair of first source/drain patterns SD1. That is, the stacked first to third semiconductor patterns SP1, SP2, and SP3 may connect the pair of first source/drain patterns SD1 to each other.

A plurality of second source/drain patterns SD2 may be provided on the second active pattern AP2. A plurality of second recesses RS2 may be formed on the second active pattern AP2. For example, the second recess RS2 may have a first width WI1 in the second direction D2. The second source/drain patterns SD2 may be provided in the second recesses RS2, respectively. The second source/drain patterns SD2 may be impurity regions of a second conductivity type (e.g., n-type). The second channel pattern CH2 may be interposed between the pair of second source/drain patterns SD2. That is, the stacked first to third semiconductor patterns SP1, SP2, and SP3 may connect the pair of second source/drain patterns SD2 to each other.

The first and second source/drain patterns SD1 and SD2 may be epitaxial patterns formed through a selective epitaxial growth (SEG) process. For example, an upper surface of each of the first and second source/drain patterns SD1 and SD2 may be higher than an upper surface of the third semiconductor pattern SP3. As another example, an upper surface of at least one of the first and second source/drain patterns SD1 and SD2 may be positioned at substantially the same level as the upper surface of the third semiconductor pattern SP3.

As an embodiment of the present disclosure, the first source/drain patterns SD1 may include a semiconductor element (e.g., SiGe) having a lattice constant greater than that of the semiconductor element of the substrate 100. Thus, the pair of first source/drain patterns SD1 may provide compressive stress to the first channel pattern CH1 therebetween. The second source/drain patterns SD2 may include the same semiconductor element (e.g., Si) as the substrate 100.

A sidewall of the first source/drain pattern SD1 may have a rugged embossed shape. That is, the sidewall of the first source/drain pattern SD1 may have a wavy profile. Sidewalls of the first source/drain pattern SD1 may protrude toward first to third inner electrodes PO1, PO2, and PO3 of a gate electrode GE, which will be described later. In addition, gate electrodes GE may be provided to cross the first and second channel patterns CH1 and CH2 and extend in a first direction D1. The gate electrodes GE may be arranged in the second direction D2 with a first pitch PI1 (refer to FIGS. 2 and 3A). Each of the gate electrodes GE may vertically overlap the first and second channel patterns CH1 and CH2.

The gate electrode GE may include a first inner electrode PO1 interposed between the active pattern AP1 or AP2 and the first semiconductor pattern SP1, a second inner electrode PO2 interposed between the first semiconductor pattern SP1 and the second semiconductor pattern SP2, a third inner electrode PO3 interposed between the second and third semiconductor patterns SP2 and SP3, and an outer electrode PO4 on the third semiconductor pattern SP3. Referring to FIG. 3D, the gate electrode GE may be provided on an upper surface TS, a bottom surface BS, and both sidewalls SW of each of the first to third semiconductor patterns SP1, SP2, and SP3. The gate electrode GE may surround the upper surface TS, the bottom surface BS, and both sidewalls SW of each of the first to third semiconductor patterns SP1, SP2, and SP3. That is, the transistor according to the present embodiment may be a three-dimensional field effect transistor (e.g., MBCFET or GAAFET) in which the gate electrode GE surrounds the channel in three dimensions.

Referring back to FIGS. 2 and 3A to 3D, a pair of gate spacers GS may be respectively disposed on both sidewalls of the outer electrode PO4 of the gate electrode GE. The gate spacers GS may extend in the first direction D1 along the gate electrode GE. Upper surfaces of the gate spacers GS may be higher than upper surfaces of the gate electrode GE. The upper surfaces of the gate spacers GS may be coplanar with an upper surface of a first interlayer insulating layer 110 to be described later. In an embodiment, the gate spacers GS may include at least one of SiCN, SiCON, and SiN. In another embodiment, the gate spacers GS may include a multi-layer formed of at least two of SiCN, SiCON, and SiN.

A gate capping pattern GP may be provided on the gate electrode GE. The gate capping pattern GP may extend in the first direction D1 along the gate electrode GE. The gate capping pattern GP may include a material having etch selectivity with respect to that of first and second interlayer insulating layers 110 and 120 to be described later. In detail, the gate capping pattern GP may include at least one of SiON, SiCN, SiCON, and SiN.

A gate insulating layer GI may be interposed between the gate electrode GE and the first channel pattern CH1 and between the gate electrode GE and the second channel pattern CH2. The gate insulating layer GI may cover the upper surface TS, the bottom surface BS, and both sidewalls SW of each of the first to third semiconductor patterns SP1, SP2, and SP3. The gate insulating layer GI may cover an upper surface of the device isolation layer ST under the gate electrode GE.

In an embodiment of the present disclosure, the gate insulating layer GI may include an interface layer and a high dielectric layer. The interface layer may include a silicon oxide layer or a silicon oxynitride layer. The high dielectric layer may include a high dielectric k material having a higher dielectric constant than that of the silicon oxide layer. For example, the high dielectric layer may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In another embodiment, the semiconductor device of the present disclosure may include a negative capacitance (NC) FET using a negative capacitor. For example, the gate insulating layer GI may include a ferroelectric material layer having ferroelectric characteristics and a paraelectric material layer having paraelectric characteristics. In some embodiments, the ferroelectric material layer may have a negative capacitance, and the paraelectric material layer may have a positive capacitance. For example, when two or more capacitors are connected in series and a capacitance of each capacitor has a positive value, a total “series” capacitance of the two capacitors is less than that of each individual capacitor. On the other hand, when at least one of the capacitances of two or more capacitors connected in series has a negative value, a total capacitance has a positive value and may be greater than an absolute value of each individual capacitance.

When the ferroelectric material layer having a negative capacitance and the paraelectric material layer having a positive capacitance are connected in series, a total capacitance value of the ferroelectric material layer and the paraelectric material layer connected in series may increase. Using the increase in total capacitance value, a transistor including a ferroelectric material layer may have a subthreshold swing (SS) of less than 60 mV/decade at room temperature.

The ferroelectric material layer may have ferroelectric characteristics. The ferroelectric material layer may include, for example, at least one of hafnium oxide, hafnium zirconium oxide, barium strontium titanium oxide, barium titanium oxide, and lead zirconium titanium oxide. Here, as an example, hafnium zirconium oxide may be a material in which zirconium (Zr) is doped with hafnium oxide. As another example, hafnium zirconium oxide may be a compound of hafnium (Hf), zirconium (Zr), and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), and cerium (Ce), dysprosium (Dy), erbium (Er), gadolinium (Gd), germanium (Ge), scandium (Sc), strontium (Sr), and tin (Sn). Depending on the type of ferroelectric material included in the ferroelectric material layer, a type of dopant included in the ferroelectric material layer may be various.

For example, when the ferroelectric material layer includes hafnium oxide, the dopant included in the ferroelectric material layer may include, for example, at least one of gadolinium (Gd), silicon (Si), zirconium (Zr), aluminum (Al), and yttrium (Y). And, when the dopant is aluminum (Al), the ferroelectric material layer may include 3 to 8 at % (atomic %) of aluminum. Here, a ratio of the dopant may be a ratio of aluminum to the sum of hafnium and aluminum. Alternatively, when the dopant is silicon (Si), the ferroelectric material layer may include 2 to 10 at % of silicon. When the dopant is yttrium (Y), the ferroelectric material layer may include 2 to 10 at % of yttrium. When the dopant is gadolinium (Gd), the ferroelectric material layer may include 1 to 7 at % of gadolinium. When the dopant is zirconium (Zr), the ferroelectric material layer may include 50 to 80 at % of zirconium.

The paraelectric material layer may have paraelectric characteristics. The paraelectric material layer may include, for example, at least one of silicon oxide and a metal oxide having a high dielectric constant. The metal oxide included in the paraelectric material layer may include, for example, at least one of hafnium oxide, zirconium oxide, and aluminum oxide, but is not limited thereto.

In some embodiments, the ferroelectric material layer and the paraelectric material layer may include the same material. The ferroelectric material layer may have ferroelectric characteristics, but the paraelectric material layer may not have ferroelectric characteristics. For example, when the ferroelectric material layer and the paraelectric material layer include hafnium oxide, a crystal structure of hafnium oxide included in the ferroelectric material layer is different from a crystal structure of hafnium oxide included in the paraelectric material layer.

The ferroelectric material layer may have a thickness having ferroelectric characteristics. A thickness of the ferroelectric material layer may be, for example, 0.5 to 10 nm, but is not limited thereto. A critical thickness representing ferroelectric properties may be various for each ferroelectric material, and thus the thickness of the ferroelectric material layer may be various depending on the ferroelectric material.

For example, the gate insulating layer GI may include one ferroelectric material layer. As another example, the gate insulating layer GI may include a plurality of ferroelectric material layers spaced apart from each other. The gate insulating layer GI may have a multilayer structure in which a plurality of ferroelectric material layers and a plurality of paraelectric material layers are alternately stacked.

Referring back to FIG. 3B, inner spacers IP may be provided on the second active pattern AP2. The inner spacers IP may be interposed between the first to third inner electrodes PO1, PO2, and PO3 of the gate electrode GE and the second source/drain pattern SD2, respectively. The inner spacers IP may be in direct contact with the second source/drain pattern SD2. Each of the first to third inner electrodes PO1, PO2, and PO3 of the gate electrode GE may be spaced apart from the second source/drain pattern SD2 by the inner spacer IP.

Referring back to FIGS. 2 and 3A to 3D, the gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work function metal for adjusting a threshold voltage of the transistor. A desired threshold voltage of the transistor may be achieved by adjusting a thickness and composition of the first metal pattern. For example, the first to third inner electrodes PO1, PO2, and PO3 of the gate electrode GE may be formed of a first metal pattern that is a work function metal. In some embodiments, the first metal pattern may include a metal nitride layer. For example, the first metal pattern may include nitrogen (N) and at least one metal selected from the group consisting of titanium (Ti), tantalum (Ta), aluminum (Al), tungsten (W), and molybdenum (Mo). Furthermore, the first metal pattern may further include carbon (C). The first metal pattern may include a plurality of stacked work function metal layers.

The second metal pattern may include a metal having lower resistance than that of the first metal pattern. For example, the second metal pattern may include at least one metal selected from the group consisting of tungsten (W), aluminum (Al), titanium (Ti), and tantalum (Ta). The outer electrode PO4 of the gate electrode GE may include a first metal pattern and a second metal pattern on the first metal pattern.

A first interlayer insulating layer 110 may be provided on the substrate 100. The first interlayer insulating layer 110 may cover the gate spacers GS and the first and second source/drain patterns SD1 and SD2. An upper surface of the first interlayer insulating layer 110 may be substantially coplanar with an upper surface of the gate capping pattern GP and an upper surface of the gate spacer GS. A second interlayer insulating layer 120 covering the gate capping pattern GP may be disposed on the first interlayer insulating layer 110. A third interlayer insulating layer 130 may be provided on the second interlayer insulating layer 120. A fourth interlayer insulating layer 140 may be provided on the third interlayer insulating layer 130. For example, the first to fourth interlayer insulating layers 110 to 140 may include a silicon oxide layer.

A logic cell SHC may have a first boundary BD1 and a second boundary BD2 that face each other in the second direction D2. The first and second boundaries BD1 and BD2 may extend in the first direction D1. The logic cell SHC may have a third boundary BD3 and a fourth boundary BD4 that face each other in the first direction D1. The third and fourth boundaries BD3 and BD4 may extend in the second direction D2.

A pair of separation structures DB facing each other in the second direction D2 may be provided on both sides of the logic cell SHC. For example, the pair of separation structures DB may be respectively provided on the first and second boundaries BD1 and BD2 of the logic cell SHC. The separation structure DB may extend parallel to the gate electrodes GE in the first direction D1. A pitch between the separation structure DB and the gate electrode GE adjacent thereto may be substantially the same as the first pitch PI1.

The separation structure DB may pass through the gate capping pattern GP and the gate electrode GE and extend into the first and second active patterns AP1 and AP2. The separation structure DB may pass through upper portions of each of the first and second active patterns AP1 and AP2. The separation structure DB may electrically separate an active region of the logic cell SHC from an active region of another adjacent cell. That is, the separation structure DB may be a single diffusion break (SDB).

Active contacts AC electrically connected to the first and second source/drain patterns SD1 and SD2 may be provided through the first and second interlayer insulating layers 110 and 120, respectively. A pair of active contacts AC may be provided on both sides of the gate electrode GE, respectively. When viewed in a plan view, the active contact AC may have a bar shape extending in the first direction D1.

In some embodiments, the active contact AC may be a self-aligned contact. That is, the active contact AC may be formed in a self-aligned manner using the gate capping pattern GP and the gate spacer GS. For example, the active contact AC may cover at least a portion of the sidewall of the gate spacer GS. Although not shown, the active contact AC may cover a portion of the upper surface of the gate capping pattern GP. The active contacts AC may be arranged in the second direction D2 with the first pitch PI1. That is, the pitch between the active contacts AC may be substantially the same as the first pitch PI1 between the gate electrodes GE.

A metal-semiconductor compound layer SC, for example, a silicide layer, may be interposed between the active contact AC and the first source/drain pattern SD1 and between the active contact AC and the second source/drain pattern SD2, respectively. The active contact AC may be electrically connected to the source/drain patterns SD1 and SD2 through the metal-semiconductor compound layer SC. For example, the metal-semiconductor compound layer SC may include at least one of titanium-silicide, tantalum-silicide, tungsten-silicide, nickel-silicide, and cobalt-silicide.

Gate contacts GC electrically connected to the gate electrodes GE may be provided through the second interlayer insulating layer 120 and the gate capping pattern GP. When viewed in a plan view, the gate contacts GC may be disposed to overlap the first active region AR1 and the second active region AR2, respectively. For example, a gate contact GC may be provided on the second active pattern AP2 (refer to FIG. 3B). As an embodiment of the present disclosure, referring to FIG. 3B, an upper portion of the active contact AC adjacent to the gate contact GC may be filled with an upper insulating pattern UIP. A bottom surface of the upper insulating pattern UIP may be lower than a bottom surface of the gate contact GC. That is, an upper surface of the active contact AC adjacent to the gate contact GC may come down lower than the bottom surface of the gate contact GC by the upper insulating pattern UIP. Accordingly, it is possible to prevent a short circuit that occurs due to contact between the gate contact GC and the active contact AC adjacent thereto.

Each of the active contact AC and gate contact GC may include a conductive pattern FM and a barrier pattern BM surrounding the conductive pattern FM. For example, the conductive pattern FM may include at least one of aluminum, copper, tungsten, molybdenum, and cobalt. The barrier pattern BM may cover sidewalls and a bottom surface of the conductive pattern FM. The barrier pattern BM may include a metal layer/metal nitride layer. The metal layer may include at least one of titanium, tantalum, tungsten, nickel, cobalt, and platinum. The metal nitride layer may include at least one of a titanium nitride layer (TiN), a tantalum nitride layer (TaN), a tungsten nitride layer (WN), a nickel nitride layer (NiN), a cobalt nitride layer (CON), and a platinum nitride layer (PtN).

A first metal layer M1 may be provided in the third interlayer insulating layer 130. For example, the first metal layer M1 may include a first power wiring M1_R1, a second power wiring M1_R2, and first wirings M1_I. Each of the wirings M1_R1, M1_R2, and M1_I of the first metal layer M1 may extend parallel to each other in the second direction D2. In more detail, the first and second power wirings M1_R1 and M1_R2 may be provided on the third and fourth boundaries BD3 and BD4 of the logic cell SHC, respectively. The first power wiring M1_R1 may extend in the second direction D2 along the third boundary BD3. The second power wiring M1_R2 may extend in the second direction D2 along the fourth boundary BD4.

The first wirings M1_I of the first metal layer M1 may be disposed between the first and second power wirings M1_R1 and M1_R2. The first wirings M1_I of the first metal layer M1 may be arranged in the first direction D1 with a predetermined pitch. For example, a pitch between the first wirings M1_I may be smaller than the first pitch PI1. A line width of each of the first wirings M1_I may be smaller than a line width of each of the first and second power wirings M1_R1 and M1_R2.

The first metal layer M1 may further include first vias VI1. The first vias VI1 may be provided under the wirings M1_R1, M1_R2, and M1_I of the first metal layer M1, respectively. The active contact AC and the wiring of the first metal layer M1 may be electrically connected to each other through the first via VI1. The gate contact GC and the wiring of the first metal layer M1 may be electrically connected to each other through the first via VI1.

The wiring of the first metal layer M1 and the first via VI1 therebelow may be formed through separate processes. That is, each of the wiring and the first via VI1 of the first metal layer M1 may be formed using a single damascene process. The semiconductor device according to the present embodiment may be formed using a process of less than 20 nm. A second metal layer M2 may be provided in the fourth interlayer insulating layer 140. The second metal layer M2 may include a plurality of second wirings M2_I. Each of the second wirings M2_I of the second metal layer M2 may have a line shape or a bar shape extending in the first direction D1. That is, the second wirings M2_I may extend parallel to each other in the first direction D1.

The second metal layer M2 may further include second vias VI2 respectively provided under the second wirings M2_1. The wiring of the first metal layer M1 and the wiring of the second metal layer M2 may be electrically connected to each other through the second via VI2. For example, the wiring of the second metal layer M2 and the second via VI2 therebelow may be formed together using a dual damascene process.

The wiring of the first metal layer M1 and the wiring of the second metal layer M2 may include the same or different conductive materials. For example, the wiring of the first metal layer M1 and the wiring of the second metal layer M2 may include at least one metal material selected from aluminum, copper, tungsten, molybdenum, ruthenium, and cobalt. Although not shown, metal layers (e.g., M3, M4, M5, etc.) stacked on the fourth insulating interlayer 140 may be additionally disposed. Each of the stacked metal layers may include wirings for routing between cells.

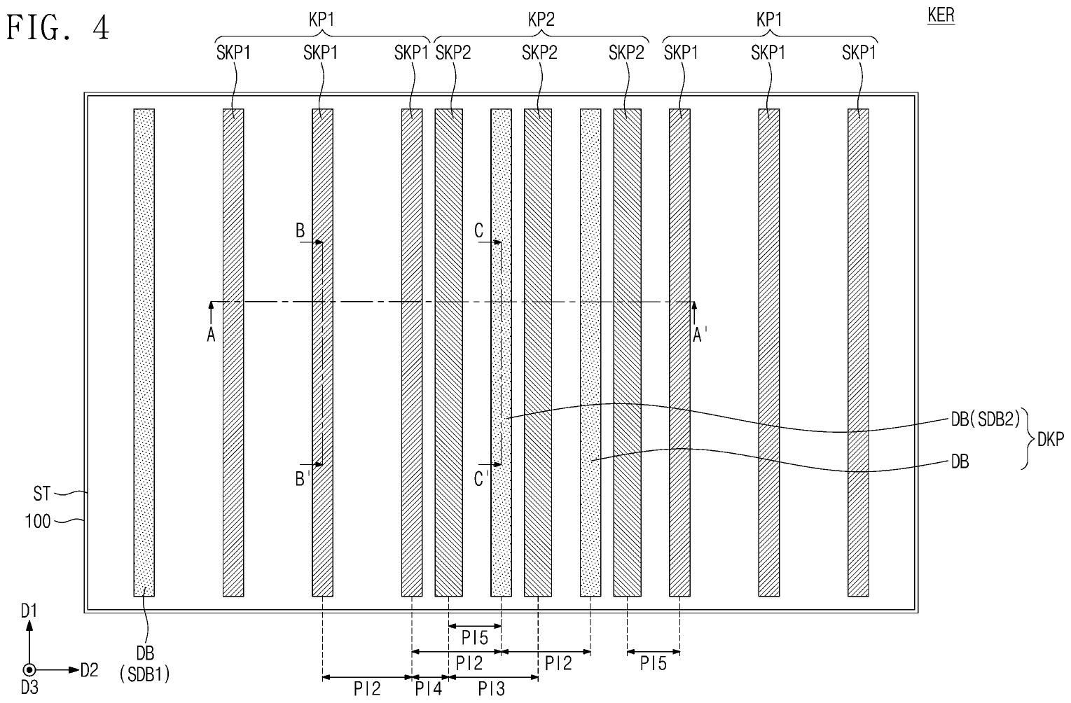

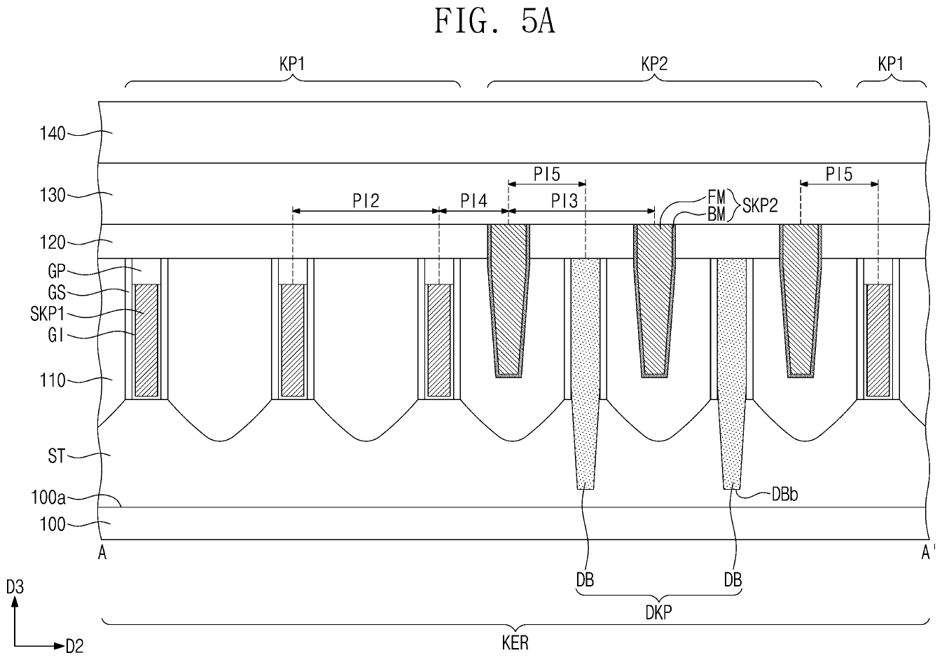

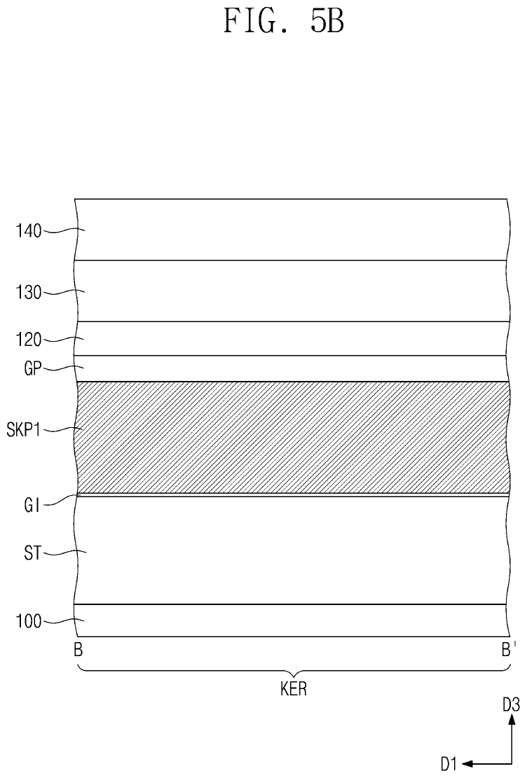

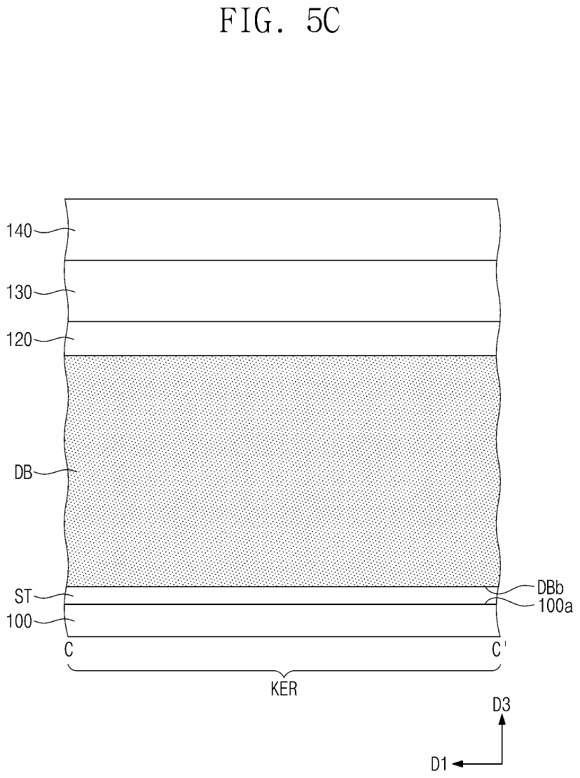

FIG. 4 is a plan view illustrating a key region of FIG. 1 for explaining a semiconductor device according to an embodiment of the present disclosure, and FIGS. 5A to 5C are cross-sectional views taken along lines A-A′, B-B′, and C-C′ of FIG. 4, respectively. FIG. 4 illustrates one key region KER among the first to third key regions KER1, KER2, and KER3 of the semiconductor chip shown in FIG. 1. For example, the key region KER of FIG. 4 may represent the first key region KER1 in the cut scribe lane CSL of FIG. 1.

A key region KER may include key patterns KP1 and KP2 used in a semiconductor chip manufacturing process. Each of the key patterns KP1 and KP2 may include an overlay key, an alignment key, or a combination thereof. The key patterns KP1 and KP2 may include first key patterns KP1 and second key patterns KP2. The first key patterns KP1 may be a lower key structure. The second key patterns KP2 may be an upper key structure. As an embodiment of the present disclosure, the first key patterns KP1 may be lower overlay keys and the second key patterns KP2 may be upper overlay keys. Alignment between a lower layer and an upper layer may be confirmed by aligning the first key patterns KP1 and the second key patterns KP2 with each other.

The first key pattern KP1 may include first sub-key patterns SKP1. The first sub-key patterns SKP1 may have a line shape extending parallel to each other in the first direction D1. For example, the first key pattern KP1 may include three first sub-key patterns SKP1. The three first sub-key patterns SKP1 may be arranged in the second direction D2 with a second pitch PI2.

The second pitch PI2 may be larger than the first pitch PI1 between the gate electrodes GE described above with reference to FIGS. 2 and 3A to 3D. For example, the second pitch PI2 may be 1.5 times to 4 times the first pitch PI1. In another embodiment, the second pitch PI2 may be substantially the same as the first pitch PI1. A first key pattern KP1 different from the first key pattern KP1 may be spaced apart from each other in the second direction D2. A second key pattern KP2 may be disposed between the first key pattern KP1 and another first key pattern KP1. For example, the second key pattern KP2 may include three second sub-key patterns SKP2. The second sub-key patterns SKP2 may have a line shape extending parallel to each other in the first direction D1. The three second sub-key patterns SKP2 may be arranged in the second direction D2 with a third pitch PI3. The third pitch PI3 may be substantially the same as or different from the second pitch PI2.

The first sub-key pattern SKP1 and the second sub-key pattern SKP2 may be adjacent to each other in the second direction D2. A pitch between the first sub-key pattern SKP1 and the second sub-key pattern SKP2 adjacent to each other may be the fourth pitch PI4. Meanwhile, the second sub-key pattern SKP2 and the first sub-key pattern SKP1 may be adjacent to each other in the second direction D2. A pitch between the second sub-key pattern SKP2 and the first sub-key pattern SKP1 adjacent to each other may be a fifth pitch PI5. The fifth pitch PI5 may be smaller than the second pitch PI2. The fifth pitch PI5 may be greater than the fourth pitch PI4. For example, a difference between the fourth pitch PI4 and the fifth pitch PI5 may be 10 nm to 30 nm.

In some embodiments, a dummy key pattern DKP may be further provided between the first key pattern KP1 and another first key pattern KP1. The dummy key pattern DKP may include at least one separation structure DB. The separation structure DB may be substantially the same as the separation structure DB described above with reference to FIGS. 2 and 3A to 3D. The dummy key pattern DKP may include two separation structures DB in some embodiments. The separation structures DB may have a line shape extending parallel to each other in the first direction D1. The separation structure DB may be disposed between the second sub-key patterns SKP2 adjacent to each other.

The separation structure DB may be formed to overlap the first sub-key pattern SKP1. Therefore, a pitch between the separation structures DB may be the above-described second pitch PI2. A pitch between the adjacent first sub-key patterns SKP1 and the separation structure DB may also be the second pitch PI2. A line width of the separation structure DB may be substantially the same as that of the first sub-key pattern SKP1.

Referring to FIGS. 4 and 5A to 5D, a device isolation layer ST may be provided on the key region KER of the substrate 100. Unlike the previously described logic cell region CER, the active pattern may be omitted on the key region KER. The first sub-key patterns SKP1 extending in the first direction D1 may be provided on the device isolation layer ST. The first sub-key patterns SKP1 may be formed simultaneously with the gate electrodes GE on the logic cell region CER. That is, a description of the first sub-key pattern SKP1 may be the same as that of the gate electrode GE on the logic cell region CER.

As described above, the first sub-key patterns SKP1 may be arranged in the second direction D2 with the second pitch PI2. The second pitch PI2 may be greater than the first pitch PI1 between the gate electrodes GE. In an embodiment of the present disclosure, a width of the first sub-key pattern SKP1 in the second direction D2 may be equal to or greater than a width of the gate electrode GE on the logic cell region CER. In the first sub-key pattern SKP1, the first to third inner electrodes PO1 to PO3 of the gate electrode GE described above may be omitted.

A pair of gate spacers GS may be respectively disposed on both sidewalls of the first sub-key pattern SKP1. A description of the gate spacers GS may be the same as that of the gate spacers GS on the logic cell region CER. A gate capping pattern GP may be provided on the first sub-key pattern SKP1. A description of the gate capping pattern GP may be the same as that of the gate capping pattern GP on the logic cell region CER.

A gate insulating layer GI may be interposed between the first sub-key pattern SKP1 and the device isolation layer ST and between the first sub-key pattern SKP1 and the gate spacers GS. A description of the gate insulating layer GI may be the same as that of the gate insulating layer GI on the logic cell region CER.

A separation structure DB passing through at least one first sub-key pattern SKP1 may be provided. The separation structure DB may pass through the gate capping pattern GP and the first sub-key pattern SKP1 and extend into the device isolation layer ST.

A bottom DBb of the separation structure DB may be positioned higher than a front surface 100a of the substrate 100. That is, a level of the bottom DBb of the separation structure DB may be higher than a level of the front surface 100a of the substrate 100. The device isolation layer ST may be interposed between the bottom DBb of the separation structure DB and the front surface 100a of the substrate 100. A pair of gate spacers GS may be provided on both sidewalls of the separation structure DB. An upper surface of the separation structure DB may be coplanar with an upper surface of the gate capping pattern GP on the first sub-key pattern SKP1.

As an embodiment, the separation structures DB may include a first single diffusion brake SDB1 and a second single diffusion brake SDB2 spaced apart in the second direction D2. The first key pattern KP1 may be disposed between the first single diffusion brake SDB1 and the second single diffusion brake SDB2. A pitch between the first sub-key pattern SKP1 adjacent to the second single diffusion break SDB2 among the first key patterns KP1 and the second sub key pattern SKP2 may be the fourth pitch PI4 described above. Meanwhile, a pitch between the second sub-key pattern SKP2 and the second single diffusion break SDB2 may be the previously described fifth pitch PI5.

First to fourth interlayer insulating layers 110 to 140 may be provided on the key region KER of the substrate 100. A description of the first to fourth interlayer insulating layers 110 to 140 may be the same as that of the first to fourth interlayer insulating layers 110 to 140 on the logic cell region CER.

Second sub-key patterns SKP2 may be provided that extend toward the substrate 100 through the first and second interlayer insulating layers 110 and 120. For example, three second sub-key patterns SKP2 may be disposed between adjacent first key patterns KP1. The separation structure DB according to the present embodiment may be disposed between adjacent second sub-key patterns SKP2. The separation structure DB may be positioned at the same level as the first key pattern KP1, but may be used as a dummy key pattern DKP instead of the first key pattern KP1. Each of the second sub-key patterns SKP2 may include a conductive pattern FM and a barrier pattern BM surrounding the conductive pattern FM. The second sub-key patterns SKP2 may be formed simultaneously with the active contacts AC. That is, a description of the second sub-key pattern SKP2 may be the same as that of the active contact AC on the logic cell region CER. As an example, an upper surface of the second sub-key pattern SKP2 may be higher than an upper surface of the first sub-key pattern SKP1. A bottom surface of the second sub-key pattern SKP2 may be higher than a bottom surface of the first sub-key pattern SKP1.

A process of measuring an alignment state of patterns on a semiconductor substrate may be performed by an overlay measurement process. Through overlay measurement, it may be confirmed whether the second key pattern KP2 disposed on an upper layer is accurately aligned and formed based on the first key pattern KP1 disposed on a lower layer. According to an embodiment of the present disclosure, the first key pattern KP1 may be a diffraction based overlay key.

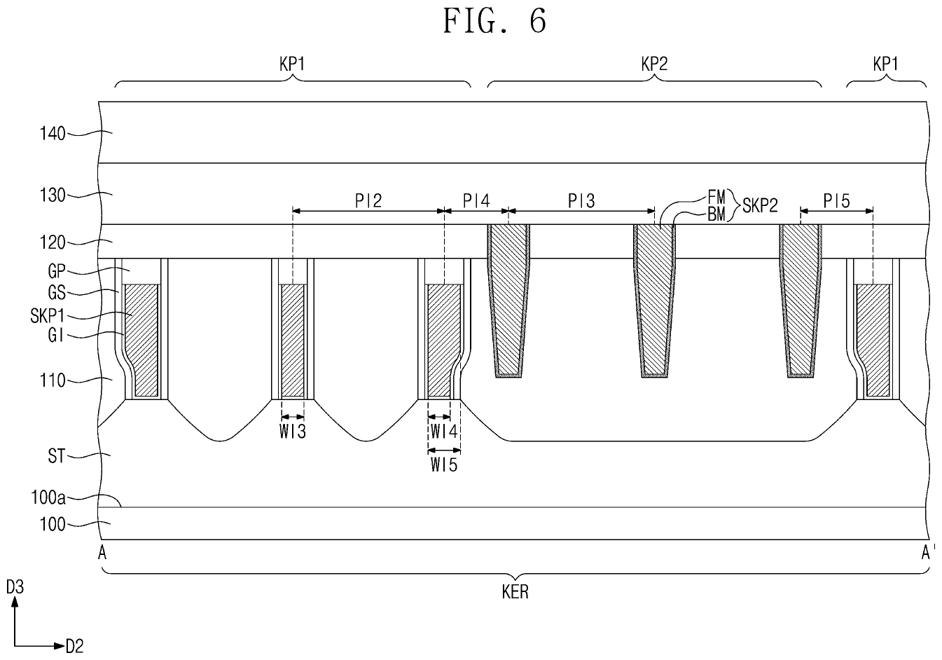

FIG. 6 illustrates a cross-section taken along the line A-A′ of FIG. 4 for explaining a semiconductor device according to a comparative example of the present disclosure. Referring to FIG. 6, a separation structure DB may be omitted in the key region KER according to the comparative example of the present disclosure. The first sub-key patterns SKP1 according to this comparative example may not be formed with a uniform pattern density at a constant pitch, but may be formed with a non-uniform pattern density. Accordingly, the first sub-key patterns SKP1 may have non-uniform line widths and different structures. That is, the first sub-key patterns SKP1 of this comparative example may be formed with low dispersion.

In detail, a second first sub-key pattern SKP1 among the three first sub-key patterns SKP1 constituting the first key pattern KP1 may have a third width WI3. Each of the first and third first sub-key patterns SKP1 among the three first sub-key patterns SKP1 may include a lower part LPP and an upper part UPP. The lower part LPP may have a fourth width WI4, and the upper part UPP may have a fifth width WI5. The fourth width WI4 may be substantially the same as the third width WI3. The fifth width WI5 may be greater than the fourth width WI4.

The first sub-key patterns SKP1 according to this comparative example may have an irregular structure, and a severe process defect, in which at least one of the first sub-key patterns SKP1 collapses, may occur. Pattern noise due to such a bad key pattern increases, and overlay measurement performance may deteriorate.

On the other hand, according to the embodiments of the present disclosure shown in FIGS. 4 and 5A to 5C, the first sub-key patterns SKP1 may be uniformly provided with a constant pitch, and some of the first sub-key patterns SKP1 may be replaced with separation structures DB. Accordingly, the first sub-key patterns SKP1 of the present disclosure constituting the first key pattern KP1 may have a uniform line width and a uniform structure. The present disclosure may provide improved overlay measurement performance by minimizing pattern noise due to a defective key pattern in the first key pattern KP1.

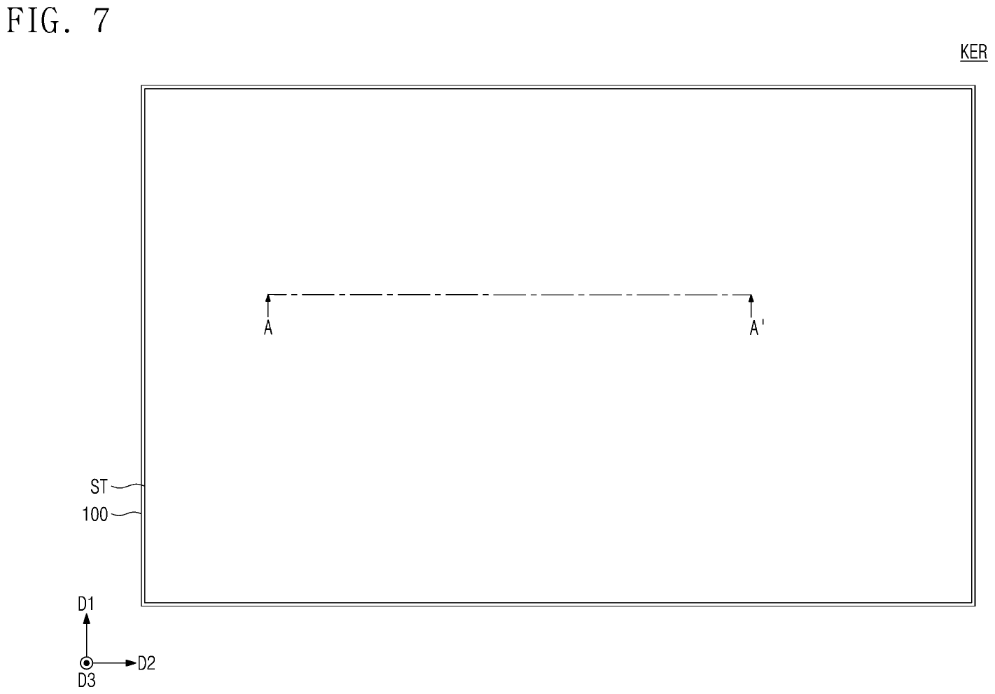

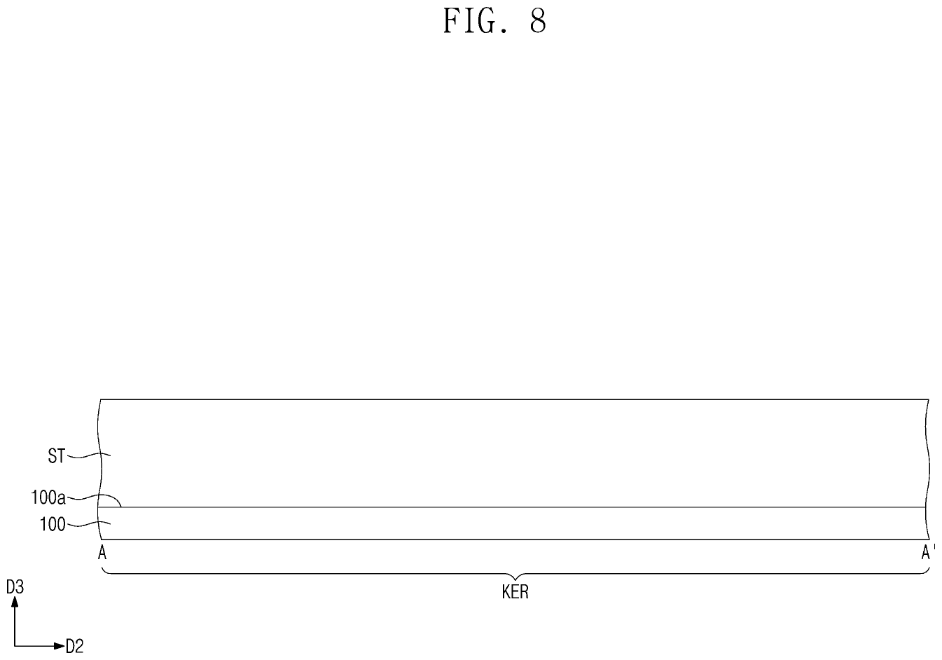

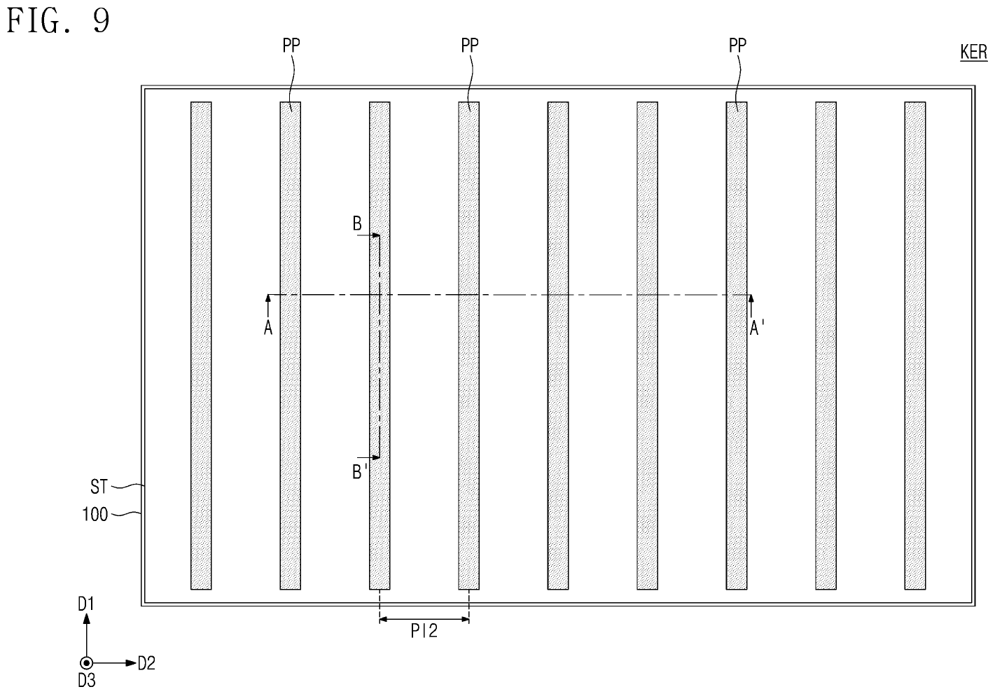

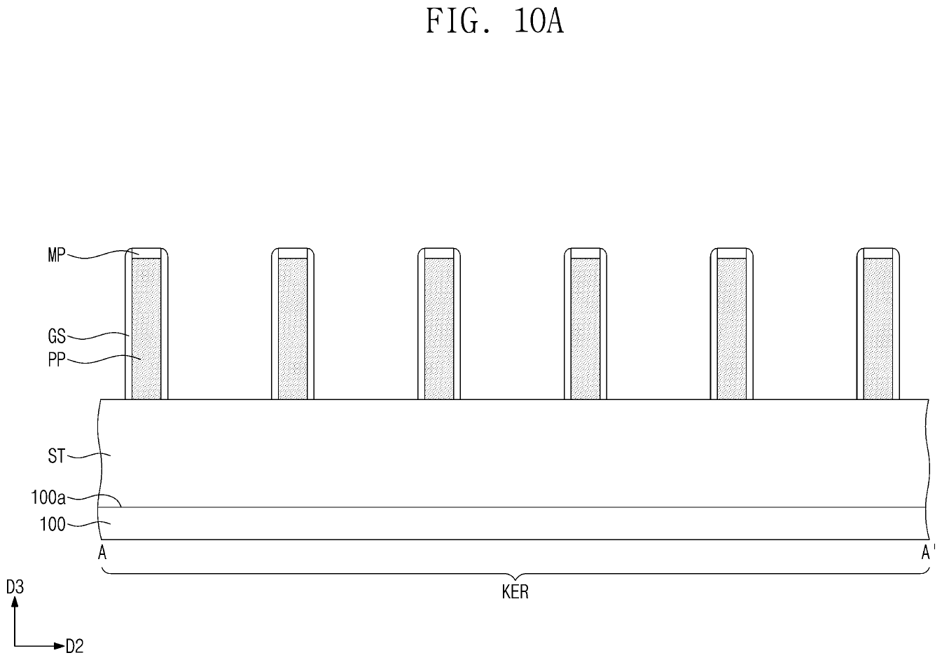

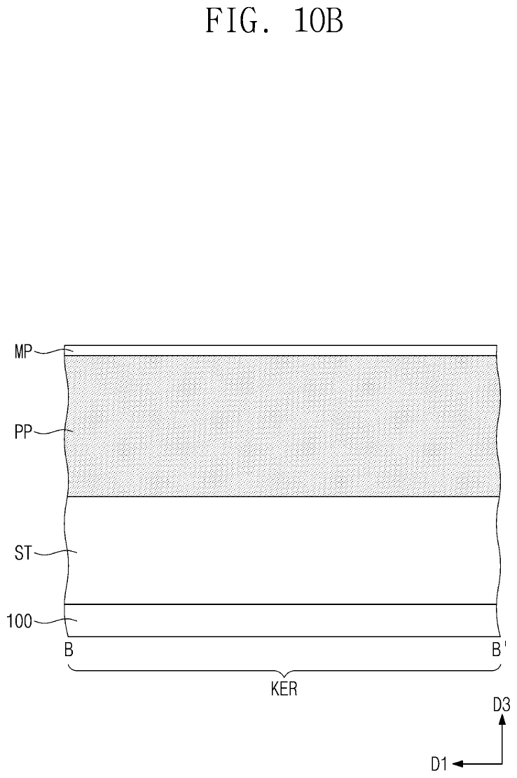

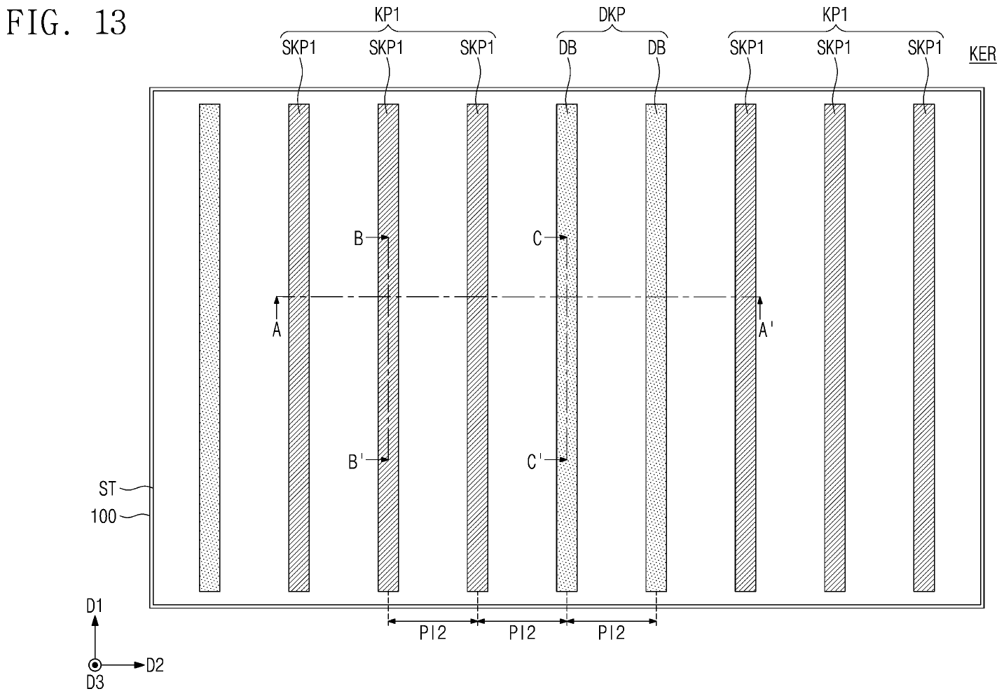

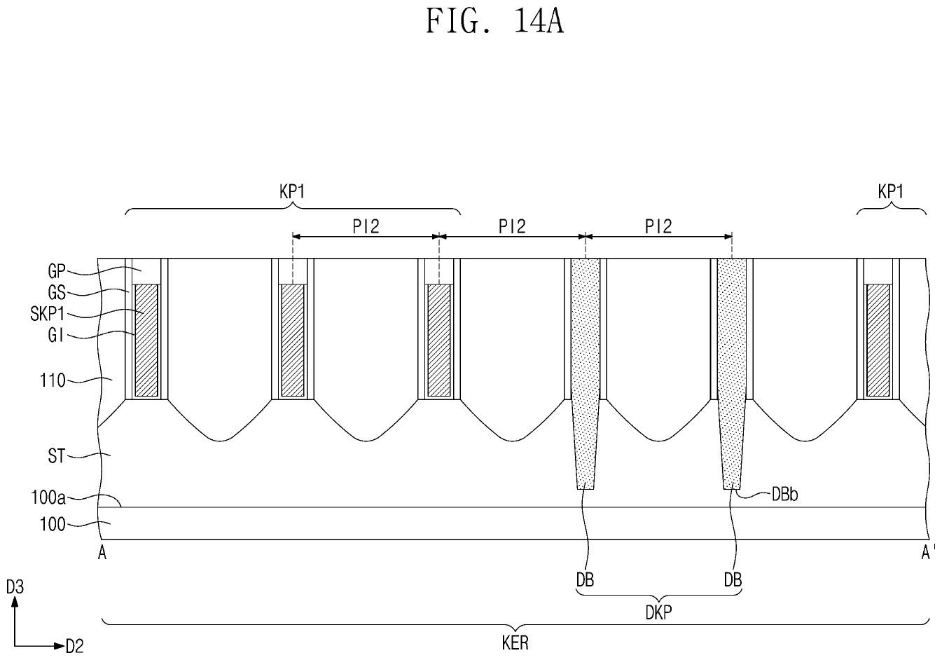

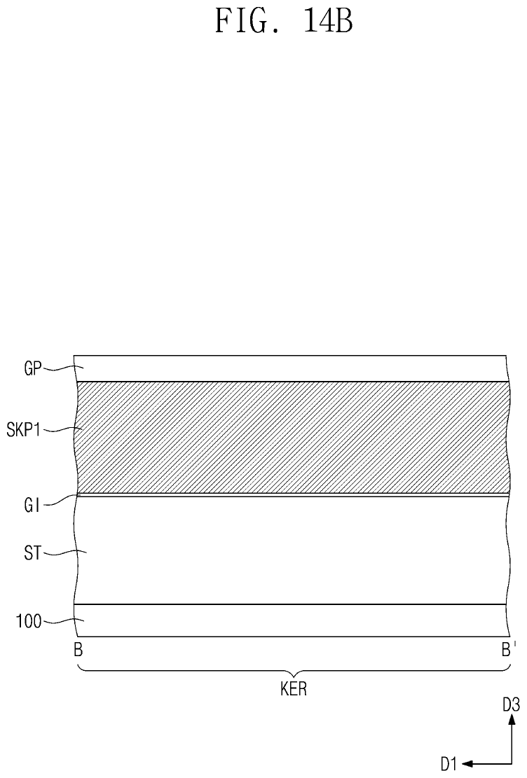

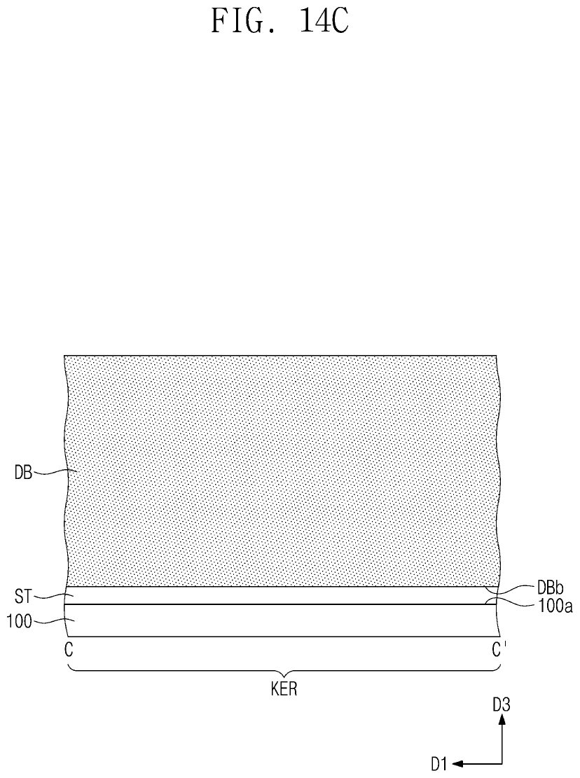

FIGS. 7, 9, 11, and 13 are plan views for explaining a method of manufacturing a semiconductor device according to embodiments of the present disclosure. FIGS. 8, 10A, 12A, and 14A are cross-sectional views taken along lines A-A′ of FIGS. 7, 9, 11, and 13, respectively. FIGS. 10B, 12B, and 14B are cross-sectional views taken along line B-B′ of FIGS. 9, 11, and 13, respectively. FIG. 14C is a cross-sectional view taken along line C-C′ of FIG. 13.

Referring to FIGS. 7 and 8, a substrate 100 including a key region KER may be provided. For example, the substrate 100 may be a silicon wafer. A device isolation layer ST may be formed on the substrate 100. The device isolation layer ST may include an insulating material such as a silicon oxide layer. The device isolation layer ST may be formed on the entire surface of the key region KER. That is, the substrate 100 of the key region KER may be completely covered by the device isolation layer ST.

Referring to FIGS. 9, 10A, and 10B, sacrificial patterns PP may be formed on the device isolation layer ST. Each of the sacrificial patterns PP may be formed in a line shape extending in a first direction D1. The sacrificial patterns PP may be arranged in a second direction D2 with a second pitch PI2. The sacrificial patterns PP according to the present disclosure may be formed in an array shape having a uniform pattern density. The sacrificial patterns PP may be replaced with first sub-key patterns SKP1 to be described later.

In detail, forming the sacrificial patterns PP includes forming a sacrificial layer on the entire surface of the substrate 100, forming hard mask patterns MP on the sacrificial layer, and then patterning the sacrificial layer using hard mask patterns MP as a selective etch mask. The sacrificial layer may include polysilicon, in some embodiments of the invention.

According to an embodiment of the present disclosure, the process of forming the hard mask patterns MP may include a lithography process using extreme ultraviolet (EUV). In the present specification, extreme ultraviolet (EUV) may refer to ultraviolet rays having a wavelength of 4 nm and 124 nm, specifically a wavelength of 4 nm and 20 nm, and more specifically, a wavelength of 13.5 nm. Extreme ultraviolet (EUV) may mean light having an energy of 6.21 eV to 124 eV, and more particularly in a range from 90 eV to 95 eV.

The lithography process using extreme ultraviolet (EUV) may include an exposure and development process using extreme ultraviolet (EUV) irradiated onto a photoresist layer. For example, the photoresist layer may be an organic photoresist containing an organic polymer such as polyhydroxystyrene. The organic photoresist may further include a photosensitive compound that reacts to extreme ultraviolet (EUV). The organic photoresist may further include a material having high EUV absorption, for example, an organometallic material, an iodine-containing material, or a fluorine-containing material. As another example, the photoresist layer may be an inorganic photoresist containing an inorganic material such as tin oxide.

The photoresist layer may be formed to be relatively thin. The photoresist patterns may be formed by developing a photoresist layer exposed to extreme ultraviolet (EUV). When viewed in a plan view, the photoresist patterns may have a line shape extending in one direction, an island shape, a zigzag shape, a honeycomb shape, or a circular shape, but are not limited to these examples.

The hard mask patterns MP may be formed by patterning one or more mask layers stacked under the photoresist patterns as an etch mask. A target layer (i.e., the sacrificial layer) may be patterned using the hard mask patterns MP as an etch mask to form desired sacrificial patterns PP on the substrate 100.

In another embodiment of the present disclosure, a process of forming the hard mask patterns MP may include a multi patterning technique (MPT). For example, the hard mask patterns MP may be formed using two or more photo masks. As another example, the hard mask patterns MP may be formed using a double patterning technique (DPT) or a quadruple patterning technique (QPT).

A pair of gate spacers GS may be formed on both sidewalls of each of the sacrificial patterns PP. Forming the gate spacers GS may include conformally forming a gate spacer layer on the entire surface of the substrate 100 and anisotropically etching the gate spacer layer. In one embodiment of the present disclosure, the gate spacer GS may be a multi-layer including at least two layers.

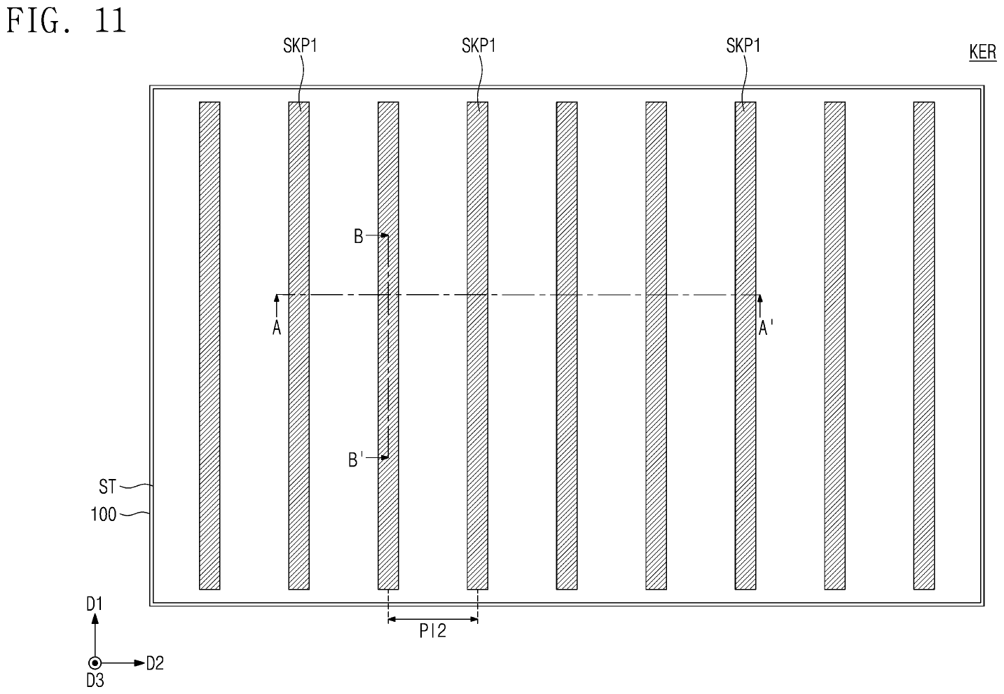

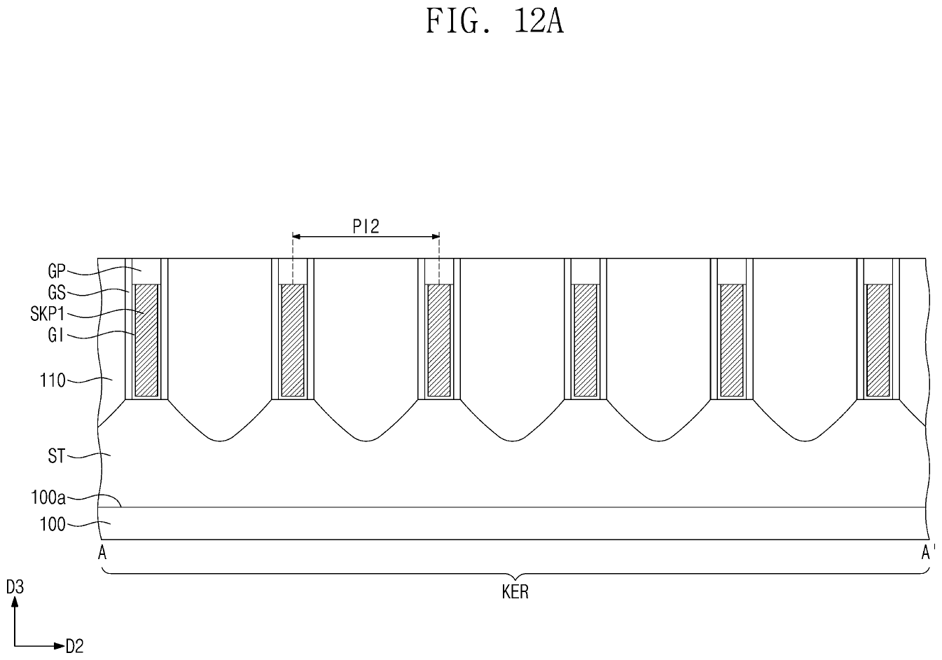

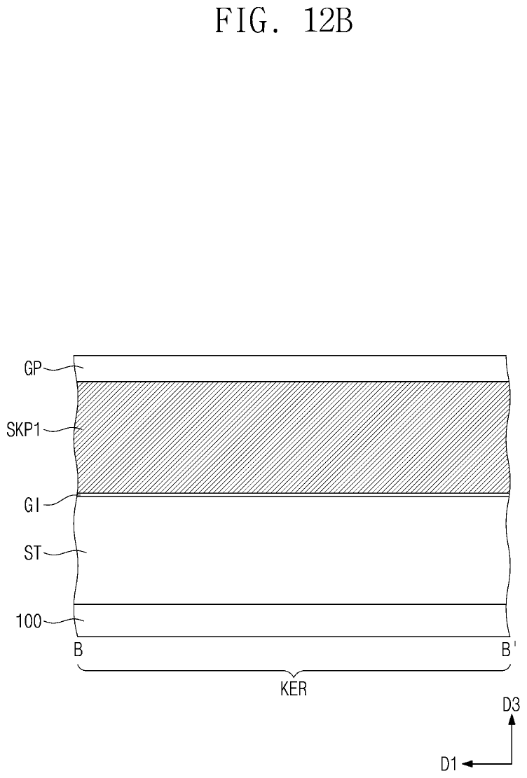

Referring to FIGS. 11, 12A, and 12B, a first interlayer insulating layer 110 may be formed to cover the device isolation layer ST, the hard mask patterns MP, and the gate spacers GS. For example, the first interlayer insulating layer 110 may include a silicon oxide layer.

The first interlayer insulating layer 110 may be planarized until upper surfaces of the sacrificial patterns PP are exposed. Planarization of the first interlayer insulating layer 110 may be performed using an etch back or chemical mechanical polishing (CMP) process. During the planarization process, all of the hard mask patterns MP may be removed. As a result, an upper surface of the first interlayer insulating layer 110 may be coplanar with upper surfaces of the sacrificial patterns PP and upper surfaces of the gate spacers GS.

The sacrificial patterns PP may be replaced with first sub-key patterns SKP1, respectively. The first sub-key patterns SKP1 may be arranged with a second pitch PI2. In detail, the exposed sacrificial patterns PP may be selectively removed. Removing the sacrificial patterns PP may include wet etching using an etchant that selectively etches the polysilicon.

A gate insulating layer GI may be formed in the empty region from which the sacrificial pattern PP is removed. For example, the gate insulating layer GI may include an interface layer and a high dielectric layer sequentially stacked. A first sub-key pattern SKP1 may be formed by filling the gate insulating layer GI with a metal. A height of the first sub-key pattern SKP1 may be reduced by being recessed. A gate capping pattern GP may be formed on the recessed first sub-key pattern SKP1. The gate electrodes GE described with reference to FIGS. 2 and 3A to 3D may be formed together with the first sub-key patterns SKP1. For example, three first sub-key patterns SKP1 adjacent to each other may constitute one first key pattern KP1. As an embodiment of the present disclosure, the first key pattern KP1 may be used as a lower overlay key.

Referring to FIGS. 13 and 14A to 14C, a separation structure DB penetrating at least one of the first sub-key patterns SKP1 may be formed. For example, a pair of adjacent first sub-key patterns SKP1 may be replaced with a pair of separation structures DB. Three adjacent first sub-key patterns SKP1 may constitute a first key pattern KP1. A pair of separation structures DB may constitute a dummy key pattern DKP. Due to the dummy key pattern DKP, the first key patterns KP1 may be relatively far apart in the second direction D2. The first key patterns KP1 adjacent to each other may be spaced apart from each other with a pitch of 3×PI2.

Forming the separation structure DB may include forming a mask exposing the first sub-key pattern SKP1 to be removed on the first interlayer insulating layer 110, anisotropically etching the exposed first sub-key pattern SKP1 using the mask as an etch mask, and filling an insulating material in the trench from which the first sub key pattern SKP1 is removed.

Referring back to FIGS. 4 and 5A to 5D, a second interlayer insulating layer 120 may be formed on the first interlayer insulating layer 110. The second interlayer insulating layer 120 may include a silicon oxide layer. Second sub-key patterns SKP2 may be formed passing through the second interlayer insulating layer 120 and the first interlayer insulating layer 110. Active contacts AC described with reference to FIGS. 2 and 3A to 3D may be formed together with the second sub-key patterns SKP2.

Three adjacent second sub-key patterns SKP2 may be formed to have a third pitch PI3. A separation structure DB may be interposed between adjacent second sub-key patterns SKP2. Three adjacent second sub-key patterns SKP2 may constitute one second key pattern KP2. The second key pattern KP2 may be formed between adjacent first key patterns KP1. As an embodiment of the present disclosure, the second key pattern KP2 may be used as an upper overlay key.

In a photolithography process for forming the active contacts AC, the previously formed first key patterns KP1 may be used as overlay keys. As an embodiment of the present disclosure, the photolithography process may be the aforementioned EUV lithography process. After performing the EUV lithography process, misalignment of the active contacts AC may be determined by detecting diffracted light diffracted from the first key patterns KP1.

A third interlayer insulating layer 130 may be formed on the second interlayer insulating layer 120. A first metal layer M1 described above with reference to FIGS. 2 and 3A to 3D may be formed in the third interlayer insulating layer 130. A fourth interlayer insulating layer 140 may be formed on the third interlayer insulating layer 130. The second metal layer M2 described above with reference to FIGS. 2 and 3A to 3D may be formed in the fourth interlayer insulating layer 140.

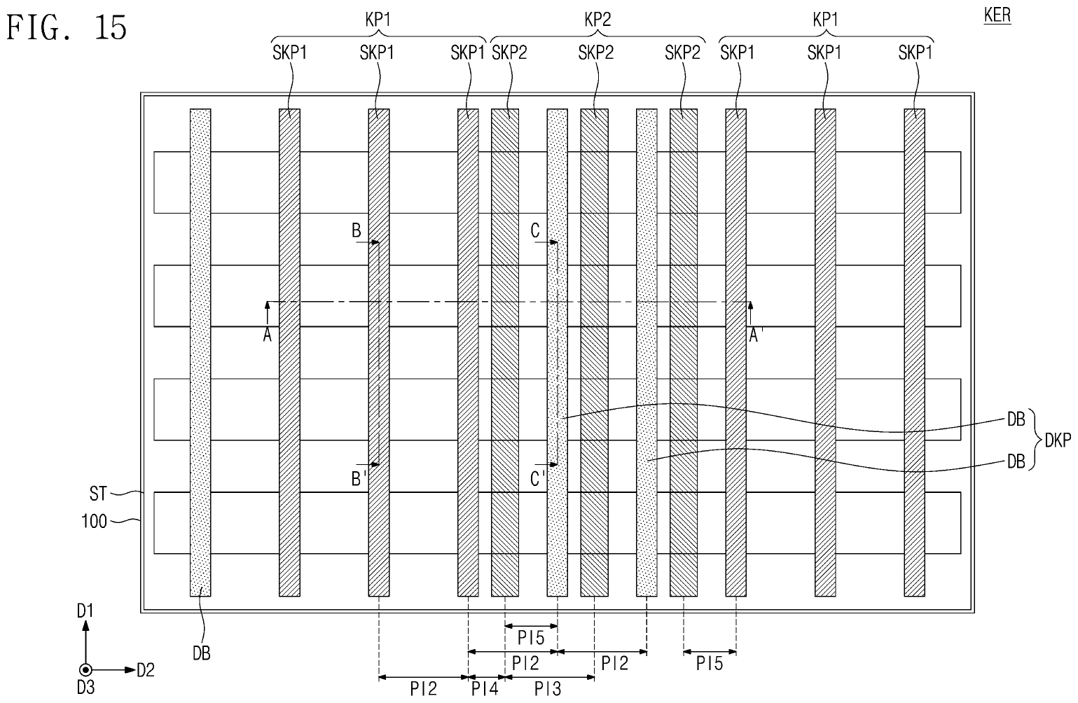

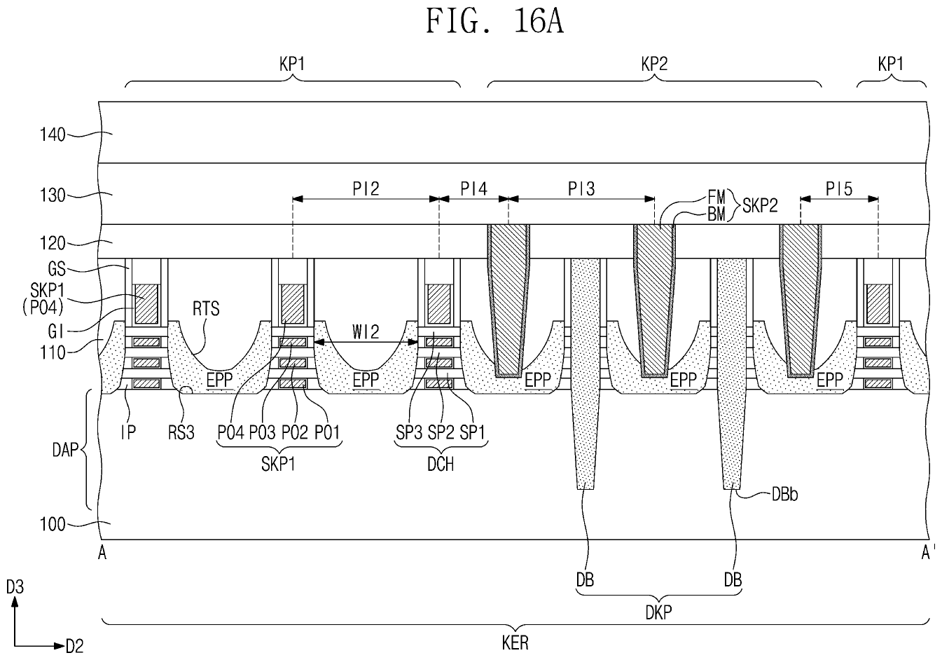

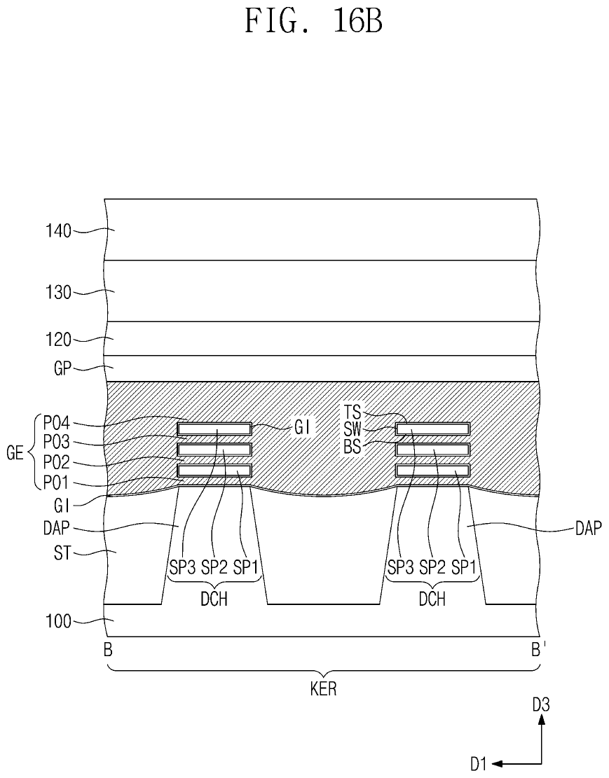

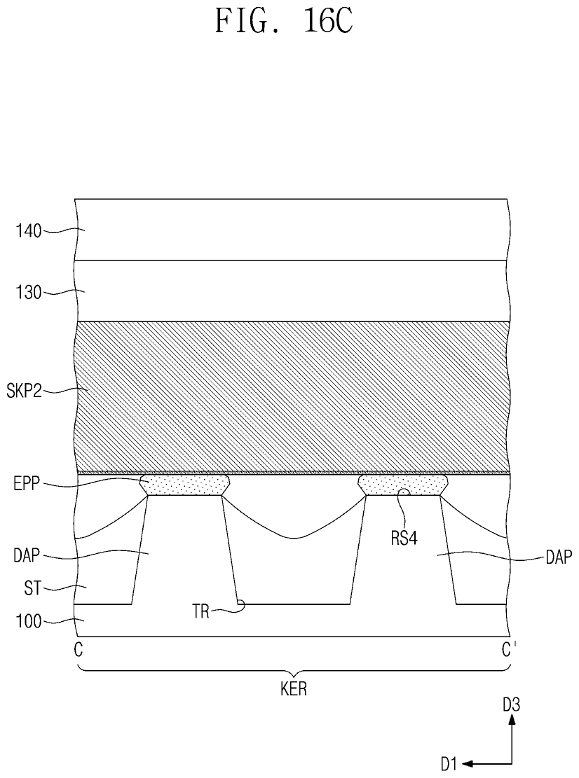

FIG. 15 is a plan view illustrating a key region of FIG. 1 for explaining a semiconductor device according to another embodiment of the present disclosure. FIGS. 16A to 16C are cross-sectional views taken along lines A-A′, B-B′, and C-C′ of FIG. 15, respectively. In the embodiments to be described later, detailed descriptions of technical features overlapping those previously described with reference to FIGS. 4 and 5A to 5D will be omitted, and differences will be described in detail.

Referring to FIGS. 15 and 16A to 16C, a plurality of dummy active patterns DAP may be provided on the key region KER of the substrate 100. The dummy active patterns DAP may be arranged in the first direction D1. The dummy active patterns DAP may extend in the second direction D2. The dummy active patterns DAP may be formed simultaneously with the first and second active patterns AP1 and AP2 on the logic cell region CER. A device layer ST may be provided to fill a trench TR between the dummy active patterns DAP.

A dummy channel pattern DCH may be provided on the dummy active pattern DAP. The dummy channel pattern DCH may include a first semiconductor pattern SP1, a second semiconductor pattern SP2, and a third semiconductor pattern SP3 sequentially stacked. The first to third semiconductor patterns SP1, SP2, and SP3 may be spaced apart from each other in a vertical direction (i.e., in the third direction D3). Each of the first to third semiconductor patterns SP1, SP2, and SP3 may be configured as a nanosheet. That is, the dummy channel pattern DCH may be a stack including stacked nanosheets. The dummy channel pattern DCH may be formed simultaneously with the first and second channel patterns CH1 and CH2 on the logic cell region CER.

A third recess RS3 may be defined between dummy channel patterns DCH adjacent to each other in the first direction D1. The third recess RS3 may be formed simultaneously with the first and second recesses RS1 and RS2 on the logic cell region CER. The third recess RS3 may have a second width WI2 in the first direction D1. The second width WI2 may be greater than the first width WI1 of the second recess RS2 described above.

An epitaxial pattern EPP filling the third recess RS3 may be provided. The epitaxial pattern EPP may connect adjacent dummy channel patterns DCH to each other. For example, the epitaxial pattern EPP may be formed simultaneously with the second source/drain pattern SD2 on the logic cell region CER. The epitaxial pattern EPP may include a silicon epitaxial pattern.

A cross section of the epitaxial pattern EPP in the third recess RS3 in the second direction D2 may have a U-shape. The epitaxial pattern EPP may include a recessed upper surface RTS. This is because the third recess RS3 is wider than the second recess RS2 on the logic cell region CER and the epitaxial pattern EPP does not completely fill the third recess RS3. A height of the epitaxial pattern EPP may decrease from one dummy channel pattern DCH to an adjacent dummy channel pattern DCH and then increase again.

First sub-key patterns SKP1 may be provided to extend in the first direction D1 while crossing the dummy active patterns DAP. The first sub-key patterns SKP1 may be formed simultaneously with the gate electrodes GE on the logic cell region CER. That is, a description of the first sub-key pattern SKP1 may be the same as that of the gate electrode GE on the logic cell region CER.

As described above, the first sub-key patterns SKP1 may be arranged in the second direction D2 with a second pitch PI2. The second pitch PI2 may be greater than the first pitch PI1 between the gate electrodes GE. In an embodiment of the present disclosure, a line width of the first sub-key pattern SKP1 may be equal to or larger than a line width of the gate electrode GE on the logic cell region CER.

The first sub-key pattern SKP1 may include a first inner electrode PO1 interposed between the dummy active pattern DAP and the first semiconductor pattern SP1, a second inner electrode PO2 interposed between the first semiconductor pattern SP1 and the second semiconductor pattern SP2, a third inner electrode PO3 interposed between the second and third semiconductor patterns SP2 and SP3, and an outer electrode PO4 on the third semiconductor pattern SP3.

Referring to FIG. 16B, the first sub key pattern SKP1 may be provided on a top surface TS, a bottom surface BS, and both sidewalls SW of each of the first to third semiconductor patterns SP1, SP2, and SP3. The first sub key pattern SKP1 may surround the top surface TS, the bottom surface BS, and both sidewalls SW of each of the first to third semiconductor patterns SP1, SP2, and SP3. In other words, a lower key structure according to the present embodiment may include a structure of a three-dimensional field effect transistor.

Referring back to FIGS. 15 and 16A to 16C, a pair of gate spacers GS may be respectively disposed on both sidewalls of the outer electrode PO4 of the first sub-key pattern SKP1. A description of the gate spacers GS may be the same as that of the gate spacers GS on the logic cell region CER. A gate capping pattern GP may be provided on the first sub-key pattern SKP1. A description of the gate capping pattern GP may be the same as that of the gate capping pattern GP on the logic cell region CER.

A gate insulating layer GI may be interposed between the first sub-key pattern SKP1 and the dummy channel pattern DCH. The gate insulating layer GI may cover the upper surface TS, the bottom surface BS, and both sidewalls SW of each of the first to third semiconductor patterns SP1, SP2, and SP3. A description of the gate insulating layer GI may be the same as that of the gate insulating layer GI on the logic cell region CER.

A dummy key pattern DKP may be provided between the first key pattern KP1 and an adjacent first key pattern KP1. The dummy key pattern DKP may include at least one separation structure DB. The separation structure DB may pass through the gate capping pattern GP and the first sub-key pattern SKP1 and extend into the dummy active pattern DAP. A description of the dummy key pattern DKP may be the same as that of FIGS. 4 and 5A to 5D.

As an embodiment of the present disclosure, the dummy key pattern DKP may include a pair of separation structures DB. An epitaxial pattern EPP having an upper surface RTS recessed between the pair of separation structures DB may be provided. A second sub-key pattern SKP2 may be provided between the pair of separation structures DB. For example, the bottom surface of the second sub-key pattern SKP2 may be in direct contact with the epitaxial pattern EPP.

First to fourth interlayer insulating layers 110 to 140 may be provided on the key region KER of the substrate 100. A description of the first to fourth interlayer insulating layers 110 to 140 may be the same as that of the first to fourth interlayer insulating layers 110 to 140 on the logic cell region CER.

Second sub-key patterns SKP2 may be provided that extend toward the substrate 100 through the first and second interlayer insulating layers 110 and 120. For example, three second sub-key patterns SKP2 may be disposed between adjacent first key patterns KP1. Description of the second sub-key patterns SKP2 may be the same as that of FIGS. 4 and 5A to 5D.

The first key pattern KP1 according to the embodiments of the present disclosure may be formed on the dummy active pattern DAP instead of on the oxide layer field (i.e., the device isolation layer ST). The first key pattern KP1 may be provided on the silicon-based dummy channel pattern DCH and the epitaxial pattern EPP, and thus a signal related to diffracted light may be increased. Also, noise related to diffracted light may be reduced. Thus, the key pattern according to the present disclosure may provide improved overlay measurement performance.

According to the present disclosure, the diffusion break may be provided on the key region and the lower key patterns may be spaced apart from each other. Accordingly, it is possible to prevent the bad key patterns from being formed in the lower key patterns, thereby minimizing the pattern noise. As a result, the present disclosure may provide the semiconductor device with the improved reliability while improving the overlay measurement performance to have the high integration.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor device, comprising:
a substrate having a key region therein;
a device isolation layer on the key region;
first key patterns on the device isolation layer; and
a dummy key pattern extending between the first key patterns, which are adjacent to each other;
wherein the first key patterns include a plurality of first sub-key patterns;
wherein the dummy key pattern includes a separation structure, which extends into the device isolation layer and through at least one of the plurality of first sub-key patterns; and
wherein a first pitch between the plurality of first sub-key patterns is substantially the same as a second pitch between the separation structure and one of the plurality of first sub-key patterns adjacent thereto.

2. The semiconductor device of claim 1, further comprising:
a second key pattern extending between adjacent ones of the first key patterns; and
wherein the first key patterns and the dummy key pattern are positioned at a first level, and the second key pattern is positioned at a second level higher than the first level.

3. The semiconductor device of claim 2, wherein a first interval between one of the first key patterns adjacent to each other and the second key pattern is different from a second interval between the second key pattern and another one of the first key patterns adjacent to each other.

4. The semiconductor device of claim 2,
wherein the second key pattern includes a plurality of second sub-key patterns, and
wherein each of the plurality of second sub-key patterns includes a conductive pattern and a barrier pattern surrounding the corresponding conductive pattern.

5. The semiconductor device of claim 4, wherein a third pitch between the plurality of second sub-key patterns is substantially the same as the first pitch.

6. The semiconductor device of claim 1,
wherein the dummy key pattern includes a pair of separation structures adjacent to each other; and
wherein a third pitch between the pair of separation structures is substantially the same as the first pitch.

7. The semiconductor device of claim 1, wherein a bottom of the separation structure is higher than a front surface of the substrate.

8. The semiconductor device of claim 1, further comprising:
an active pattern on a logic cell region of the substrate;
a channel pattern on the active pattern;
a source/drain pattern electrically connected to the channel pattern; and
a gate electrode on the channel pattern;
wherein the gate electrode includes a plurality of gate electrodes; and
wherein a third pitch between the plurality of gate electrodes is smaller than the first pitch.

9. The semiconductor device of claim 8, wherein the channel pattern includes a plurality of semiconductor patterns that are vertically stacked and spaced apart from each other; and wherein the gate electrode surrounds a top surface, a bottom surface, and both sidewalls of each of the plurality of semiconductor patterns.

10. The semiconductor device of claim 1, wherein the first key patterns further include a plurality of capping patterns respectively provided on the plurality of first sub-key patterns; and wherein upper surfaces of the plurality of capping patterns are coplanar with an upper surface of the separation structure.

11. A semiconductor device, comprising:
a substrate including a key region;
a device isolation layer on the key region;
first key patterns on the device isolation layer; and
a dummy key pattern extending between the first key patterns, which are adjacent to each other;
wherein the first key patterns are spaced apart from each other by the dummy key pattern;
wherein each of the first key patterns includes a first sub-key pattern, a first spacer on a sidewall of the first sub-key pattern, and a capping pattern on the first sub-key pattern;
wherein the dummy key pattern includes a separation structure and a second spacer on a sidewall of the separation structure; and
wherein an upper surface of the capping pattern is substantially coplanar with an upper surface of the separation structure.

12. The semiconductor device of claim 11, further comprising:
a second key pattern extending between the adjacent first key patterns;
wherein the first key patterns and the dummy key pattern are positioned at a first level; and
wherein the second key pattern is positioned at a second level higher than the first level.

13. The semiconductor device of claim 12, wherein a first interval between one of the first key patterns adjacent to each other and the second key pattern is different from a second interval between the second key pattern and another one of the first key patterns adjacent to each other.

14. The semiconductor device of claim 12, wherein the second key pattern includes a plurality of second sub-key patterns; and wherein each of the plurality of second sub-key patterns includes a conductive pattern and a barrier pattern surrounding the conductive pattern.

15. The semiconductor device of claim 11, wherein the first sub-key pattern includes a plurality of first sub-key patterns; wherein the separation structure includes a plurality of separation structures; and wherein a pitch between the plurality of first sub-key patterns is substantially the same as a pitch between the separation structures.

16. A semiconductor device, comprising:
a substrate including a key region;
a device isolation layer on the key region;
a first single diffusion brake and a second single diffusion brake on the device isolation layer;
a plurality of first sub-key patterns arranged between the first and second single diffusion brakes; and
a second sub key pattern extending between the second single diffusion break and one of the plurality of first sub-key patterns that is adjacent to the second single diffusion break; and
wherein a first pitch between the adjacent first sub-key pattern and the second sub-key pattern is different from a second pitch between the second sub-key pattern and the second single diffusion break.

17. The semiconductor device of claim 16, wherein a third pitch between the plurality of first sub-key patterns is substantially the same as a fourth pitch between the second single diffusion break and the one of the plurality of first sub-key patterns.

18. The semiconductor device of claim 16, wherein the first sub-key patterns and the first and second single diffusion breaks are positioned at a first level, and the second sub-key pattern is positioned at a second level higher than the first level.

19. The semiconductor device of claim 16, further comprising:
a first spacer on a sidewall of each of the plurality of first sub-key patterns; and
a second spacer on a sidewall of each of the first and second single diffusion brakes.

20. The semiconductor device of claim 16, wherein the second sub-key pattern includes a conductive pattern and a barrier pattern surrounding the conductive pattern.
